(19) United States
(12) Patent Application Publication
(10) Pub. No.: US 2025/0351417 A1
(43) Pub. Date: Nov. 13, 2025

(54) SEMICONDUCTOR DEVICES AND METHODS OF FORMATION

(71) Applicant: Taiwan Semiconductor Manufacturing Company, Ltd., Hsinchu (TW)

(72) Inventors: Huei Tang WANG, Tainan City (TW); Jia-Yi WANG, Kaohsiung City (TW); Yuan Tsung TSAI, Tainan City (TW); Tsung-Yin HSU, Tainan City (TW); Ying Ming WANG, Tainan City (TW); Hsien Hua TSENG, Tainan City (TW)

(21) Appl. No.: 18/659,240

(22) Filed: May 9, 2024

(51) Int. Cl. H01L 29/78; H01L 21/762; H01L 27/092; H01L 29/66

(52) U.S. Cl. CPC H10D 30/62; H01L 21/76205; H10D 30/024; H10D 30/65; H10D 84/853

(57) ABSTRACT

A semiconductor device is formed such that isolation regions between a medium voltage transistor region and a low voltage transistor region are manufactured to have different properties than isolation regions between low voltage transistors in the low voltage transistor region. A dual STI technique described herein is used to form the isolation regions between the low voltage transistors in the low voltage transistor region using low voltage transistor isolation design rules may, and additional STI formation operations may be performed to form the isolation regions between the low voltage transistor region and the medium voltage transistor region. In particular, the dual STI technique described herein may be used to form the isolation regions between the low voltage transistor region and the medium voltage transistor region such that these isolation regions are deeper than other isolation regions in the semiconductor device.

### BACKGROUND

A high voltage transistor includes a transistor that is configured to operate at greater voltages (e.g., a high gate voltage, a high drain voltage) relative to medium voltage transistors and low voltage transistors, and a medium voltage transistor includes a transistor that is configured to operate at greater voltages (e.g., a high gate voltage, a high drain voltage) relative to low voltage transistors. The maximum voltages that can be endured (without being damaged) by medium voltage transistors may be lower than the maximum voltages that can be endured (without being damaged) by high voltage transistors, and the maximum voltages that can be endured (without being damaged) by low voltage transistors are lower than the maximum voltages that can be endured (without being damaged) by medium voltage transistors. Low voltage transistors may be used in applications such as logic circuits (e.g., processors), memory (e.g., static random access memory (SRAM), and/or input/output (I/O) circuits, among other examples. High voltage transistors and medium voltage transistors may be used in applications such as integrated circuit (IC) drivers, power ICs, shifter circuits, image sensors, power management, radio frequency (RF) power amplifiers, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1L are diagrams of an example of forming a portion of a semiconductor device described herein.

FIG. 2 is a diagram of an example of a semiconductor device described herein.

FIG. 3 is a diagram of an example of a semiconductor device described herein.

FIG. 4 is a diagram of an example of a semiconductor device described herein.

FIGS. 5A and 5B are diagrams of examples of transistor structures for various types of transistors that may be included in a semiconductor device described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

High voltage transistors and medium voltage transistors may be integrated into a semiconductor device along with low voltage transistors that may be included in logic circuitry of the semiconductor device. Low voltage transistors may include fin-based transistors such as fin field effect transistors (finFETs), nanostructure transistors (e.g., nanowire transistors, nanosheet transistors, gate-all-around (GAA) transistors, multi-bridge channel transistors, nanoribbon transistors), and/or another type of transistors that have smaller feature sizes and/or may be spaced closer together compared to the spacing between high voltage transistors and/or medium voltage transistors. While this enables high voltage transistors, medium voltage transistors, and low voltage transistors to be manufactured using similar semiconductor manufacturing processes and to share manufacturing operations, high voltage transistors and/or medium voltage transistors may have different spacing rules compared to low voltage transistors.

For example, a medium voltage transistor may include a laterally diffused (or laterally double diffused) metal-oxide semiconductor (LDMOS) transistor that has a drift region in which charge carriers are laterally diffused to facilitate distribution of an electric field between a gate structure and a source/drain region of the medium voltage transistor. The lateral diffusion of charge carriers in the drift region enables the medium voltage transistor to withstand higher gate and source/drain voltages than low voltage transistors. However, because of the large diffusion area of charge carriers in the medium voltage transistor, the medium voltage transistor may be susceptible to current leakage into a substrate (sometimes referred to as punch-through current leakage) in which the medium voltage transistor is formed. Thus, the spacing between the medium voltage transistor and a low voltage transistor may be greater than the spacing between low voltage transistors to prevent or reduce the likelihood of the current leakage from the medium voltage transistor degrading the performance of the low voltage transistor and/or damaging the low voltage transistor.

Thus, while high voltage transistors, medium voltage transistors, and low voltage transistors may be manufactured using similar processes, the same semiconductor manufacturing operations used to manufacture low voltage transistors may not be fully suitable for manufacturing high voltage transistors and medium voltage transistors.

In some implementations described herein, a semiconductor device is formed such that isolation regions between a medium voltage transistor region and a low voltage transistor region are manufactured to have different properties than isolation regions between low voltage transistors in the low voltage transistor region. A dual shallow trench isolation (STI) technique described herein is used to form the isolation regions between the low voltage transistors in the low voltage transistor region using low voltage transistor isolation design rules, and additional STI formation operations may be performed to form the isolation regions between the low voltage transistor region and the medium voltage transistor region. In particular, the dual STI technique described herein may be used to form the isolation regions between the low voltage transistor region and the medium voltage transistor region such that these isolation regions are deeper than other isolation regions in the semiconductor device.

In this way, the dual STI technique described herein enables the isolation regions between the low voltage transistor region and the medium voltage transistor region to be formed using a different set of design rules such that greater electrical isolation may be provided between the low voltage transistor region and the medium voltage transistor region, and lesser spacing (for greater transistor density) between low voltage transistors in the low voltage transistor region may be achieved. This enables medium voltage transistors in the medium voltage transistor region to be positioned closer to the low voltage transistors in the low voltage transistor region with minimal to no increase in likelihood of current leakage from the medium voltage transistors impacting the performance of the low voltage transistors and/or damaging the low voltage transistors. Thus, the dual STI technique described herein may enable increased device density to be achieved in a semiconductor device that includes high voltage transistors, medium voltage transistors, and low voltage transistors.

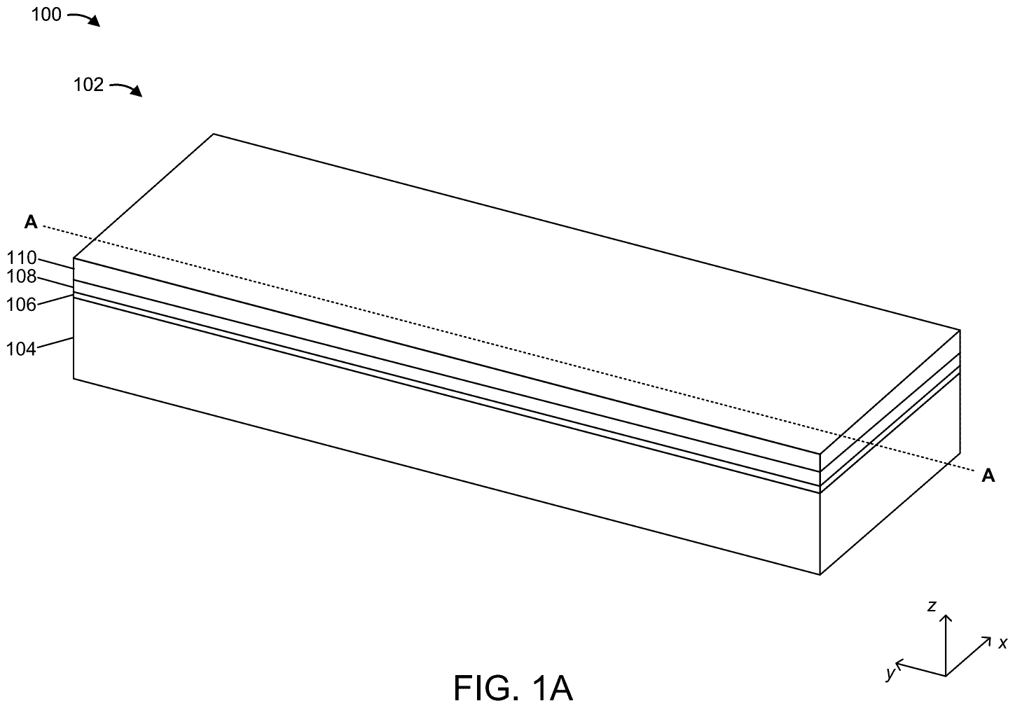

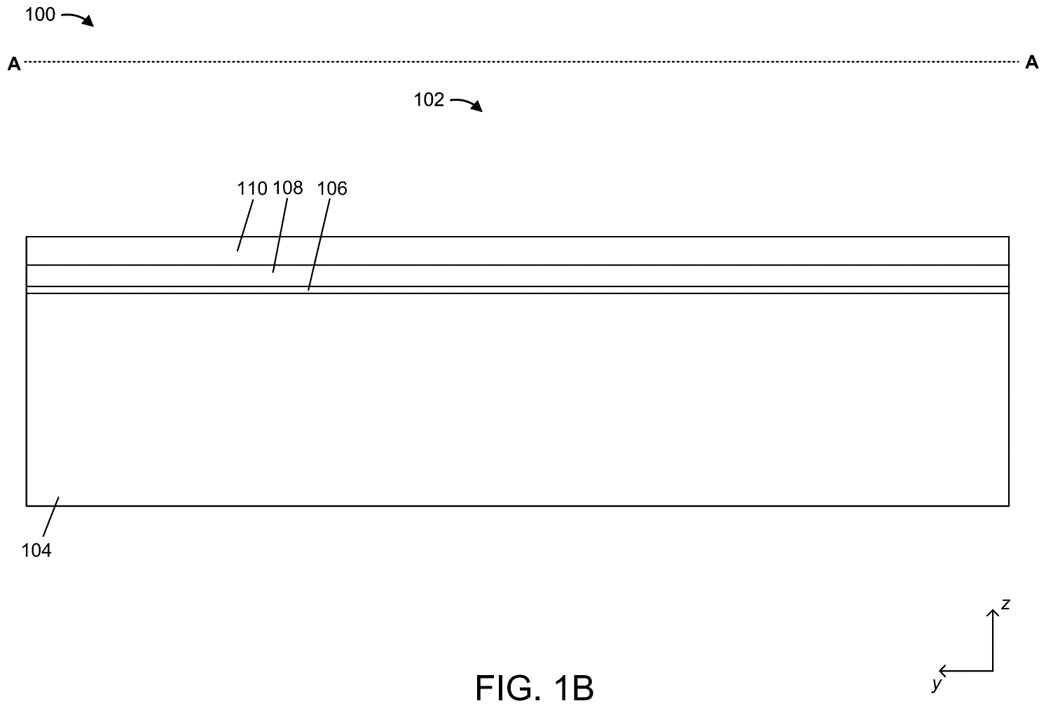

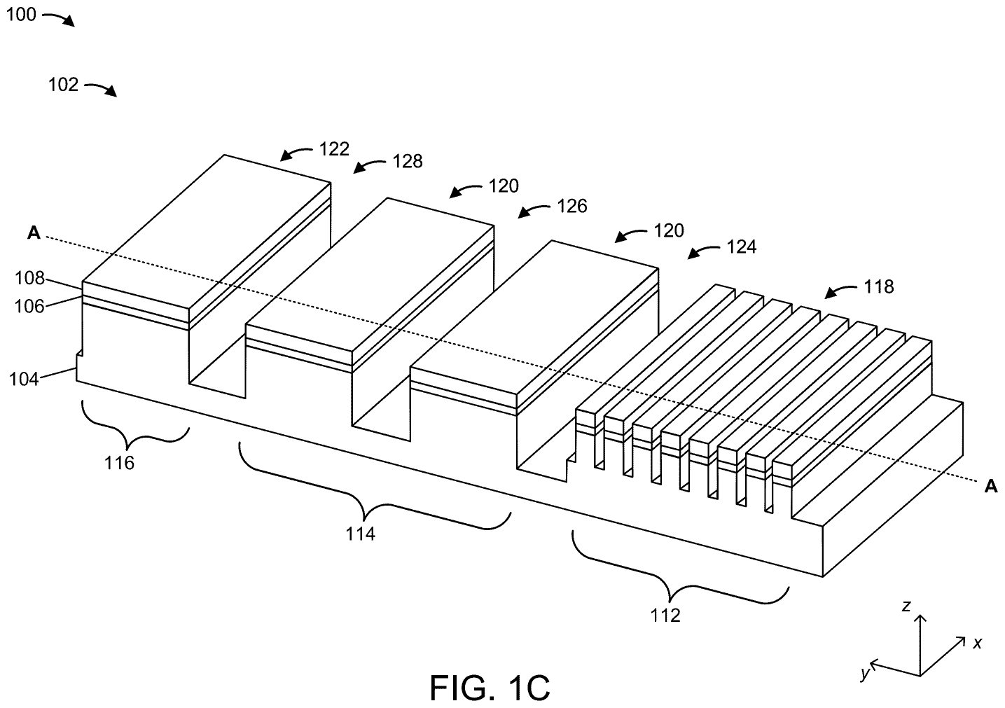

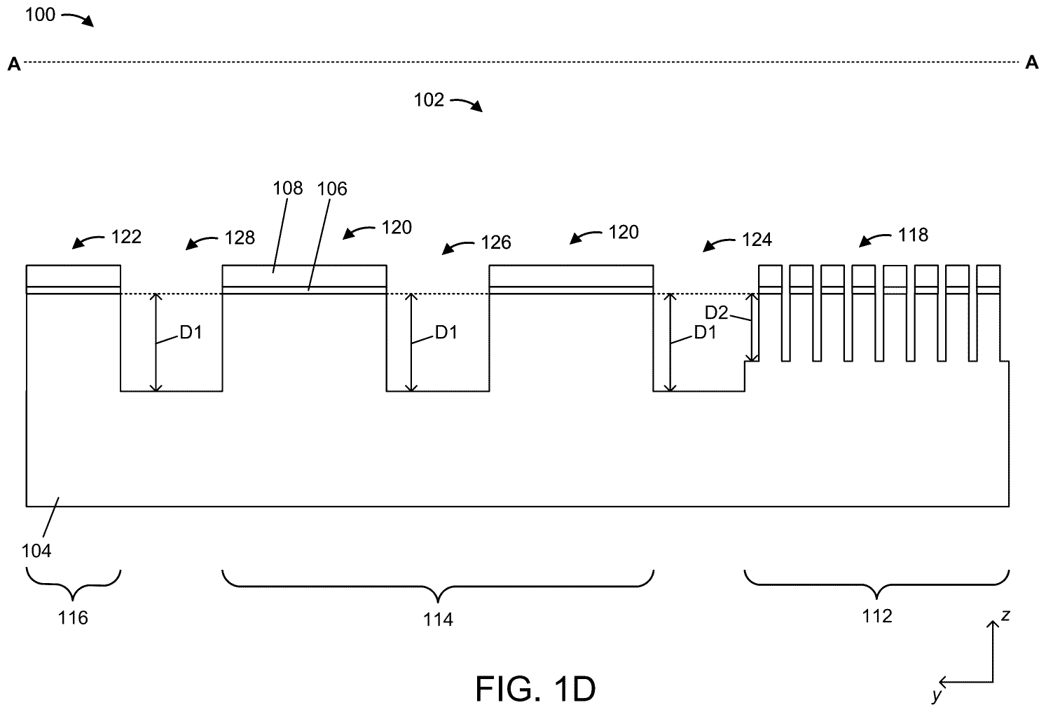

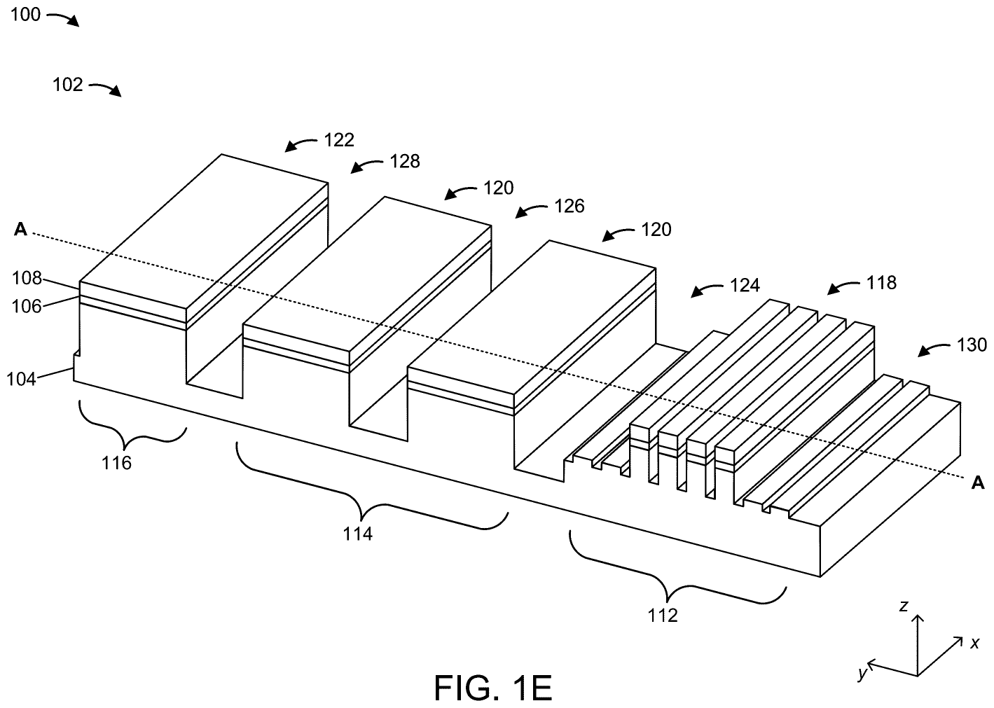

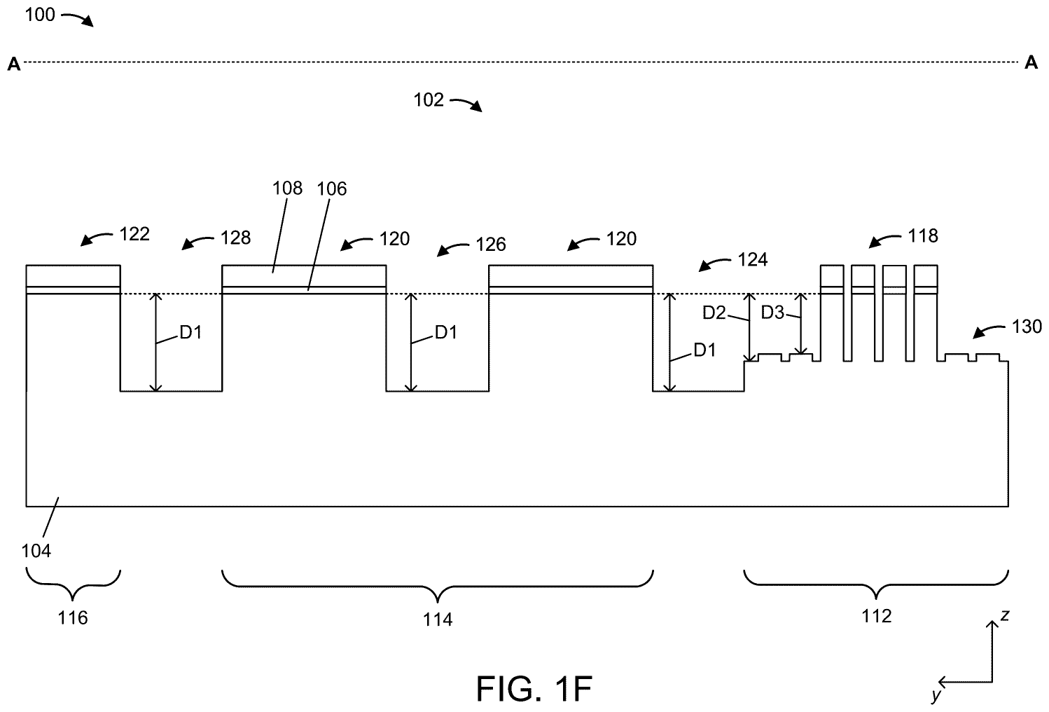

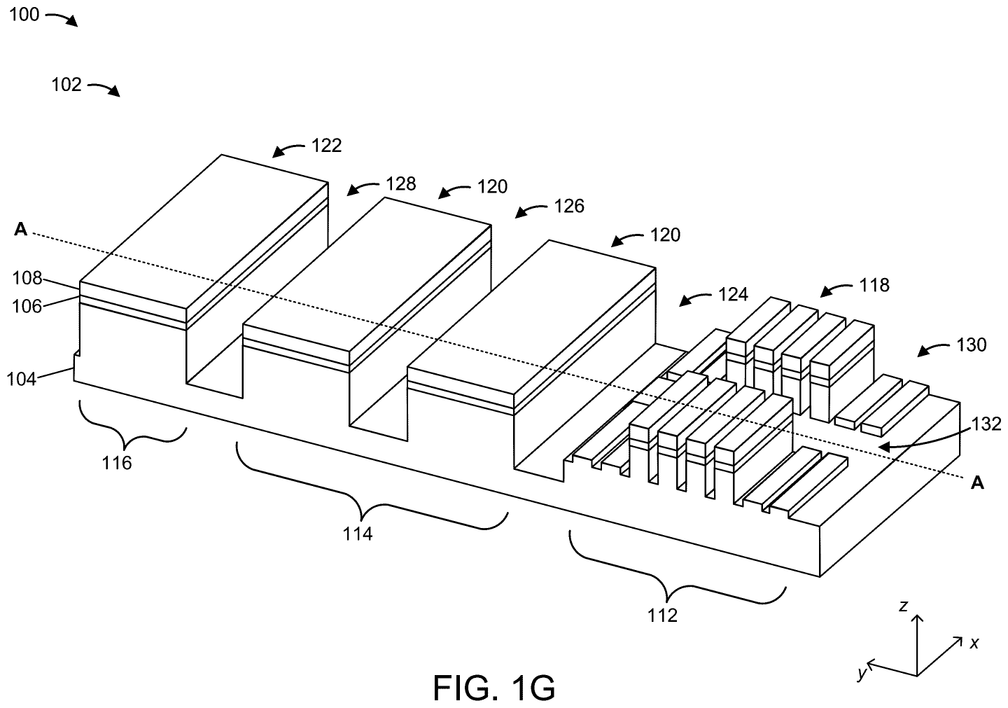

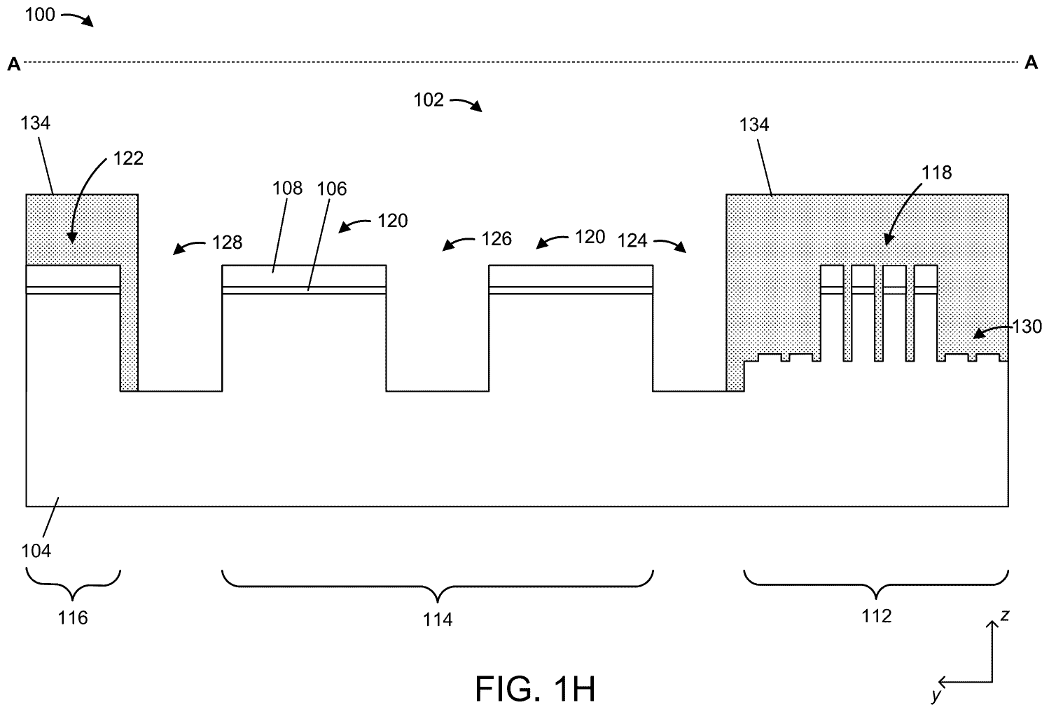

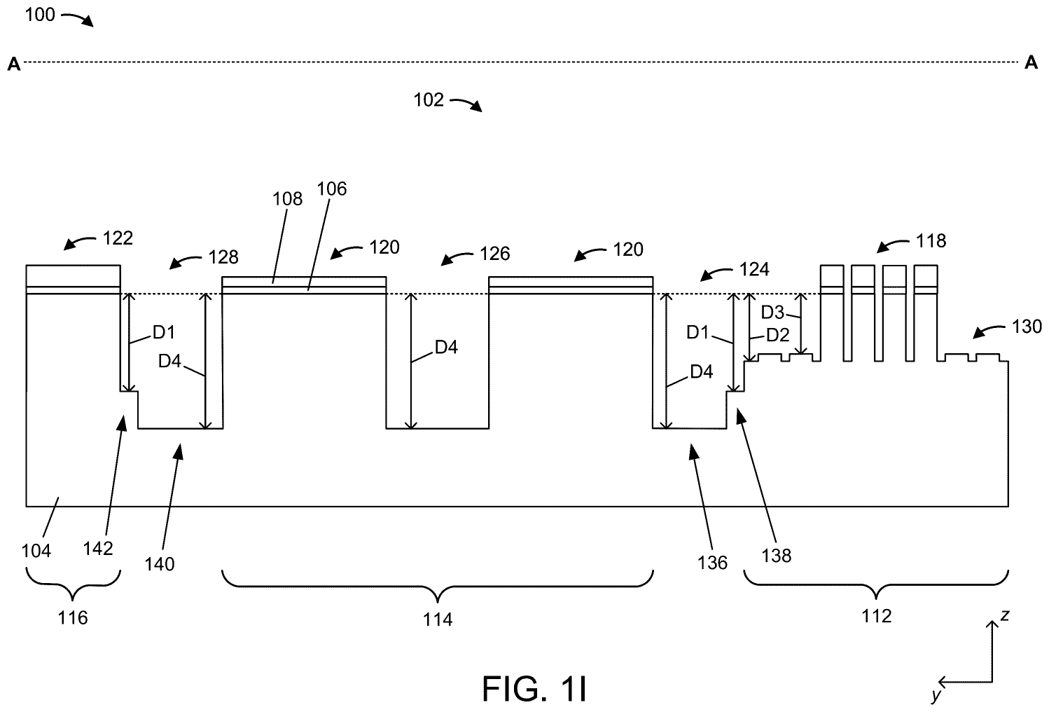

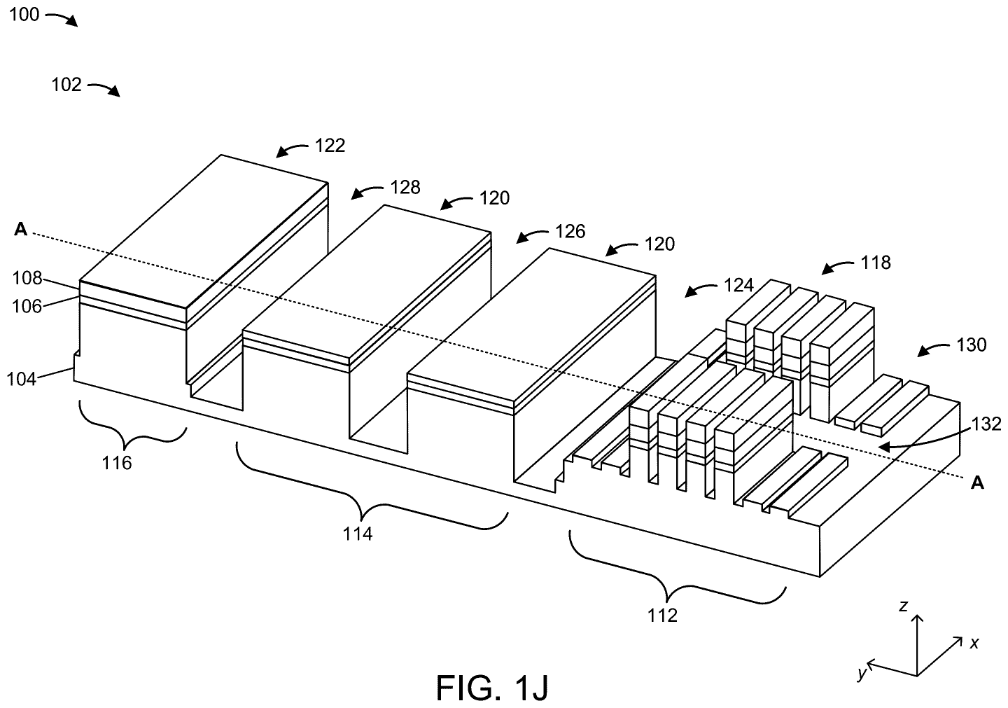

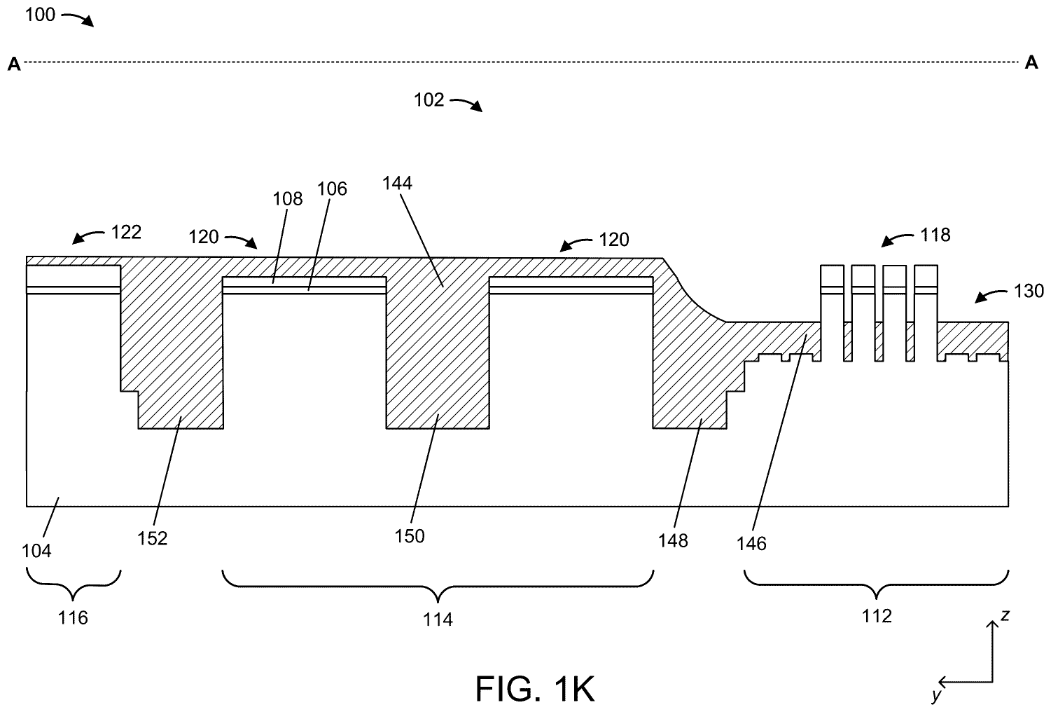

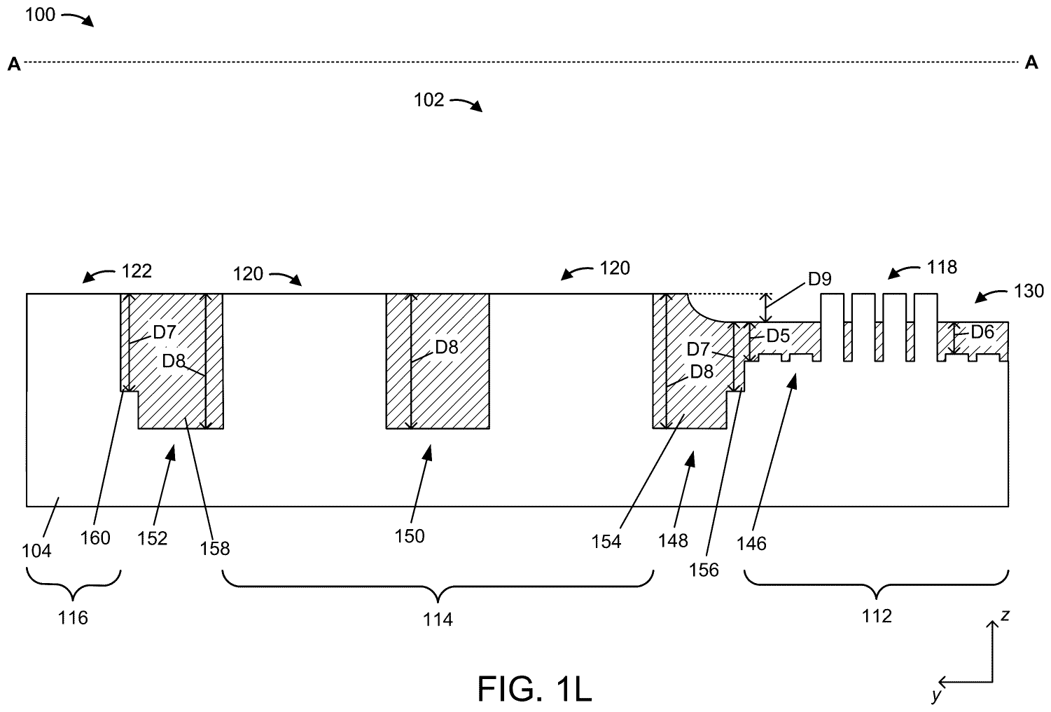

FIGS. 1A-1L are diagrams of an example 100 of forming a portion of a semiconductor device 102 described herein. The example 100 includes an example of forming active regions, and associated isolation regions between the active regions, for various transistor regions of the semiconductor device 102. In particular, the semiconductor device 102 may be manufactured to include a plurality of transistors, and the active regions may be active regions of the transistors. The transistors may include one or more low voltage transistors in a low voltage transistor region and one or more medium voltage transistors in a medium voltage transistor region. The semiconductor device 102 may additionally include one or more high voltage transistors in a high voltage transistor region.

Turning to FIGS. 1A and 1B, a substrate 104 for the semiconductor device 102 may be provided. FIG. 1A illustrates a perspective view of the semiconductor device 102, and FIG. 1B illustrates a cross-section view of the semiconductor device 102 along the line A-A in FIG. 1A. The substrate 104 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The substrate 104 may be provided as a semiconductor wafer or another type of semiconductor work piece.

As further shown in FIGS. 1A and 1B, a plurality of layers may be formed above and/or on the substrate 104. The layers may include a pad oxide layer 106 above and/or on the substrate 104, a hard mask layer 108 above and/or on the pad oxide layer 106, and/or a fin patterning layer 110 above and/or on the hard mask layer 108, among other examples.

The pad oxide layer 106 may include one or more oxide materials, such as a silicon oxide (SiOₓ such as SiO₂), silicon oxynitride (SiON), silicon oxycarbide (SiOC), fluoride-doped silicate glass (FSG), undoped silicate glass (USG), and/or another suitable dielectric oxide material. Additionally and/or alternatively, the pad oxide layer 106 may include another dielectric material. In some implementations, the pad oxide layer 106 is formed to a thickness that is included in a range of approximately 30 angstroms to approximately 50 angstroms. However, other values for the range are within the scope of the present disclosure.

In some implementations, the hard mask layer 108 includes one or more nitride materials, such as a silicon nitride (SiₓN_{y} such as Si₃N₄), a silicon carbon nitride (SiCN), a silicon oxycarbonnitride (SiOCN), and/or another suitable dielectric nitride material. Additionally and/or alternatively, the hard mask layer 108 may include another dielectric material. In some implementations, the hard mask layer 108 is formed to a thickness that is included in a range of approximately 360 angstroms to approximately 400 angstroms. However, other values for the range are within the scope of the present disclosure.

The fin patterning layer 110 may include a sacrificial layer that is used for patterning the substrate 104 to form the active regions in the substrate 104. For example, the fin patterning layer 110 may be used to form a layer of mandrels above the substrate 104 so that the mandrels can be used to form spacers that are then used to etch the substrate 104 to form the active regions. In some implementations, the fin pattern layer 110 includes a semiconductor layer having a crystalline or polycrystalline structure. For example, the fin patterning layer 110 may include single-crystalline silicon (Si), polycrystalline silicon (Si), and/or other suitable materials. In some implementations, the fin patterning layer 110 has a thickness that is included in a range of approximately 100 angstroms and approximately 500 angstroms. However, other values for the range are within the scope of the present disclosure.

A deposition tool may be used to deposit the pad oxide layer 106 and/or the hard mask layer using a chemical vapor deposition technique (e.g., plasma enhanced CVD (PECVD), atmospheric pressure CVD (APCVD), low pressure CVD (LPCVD), high density plasma CVD (HDPCVD)), an atomic layer deposition (ALD), atomic layer CVD (ALCVD), physical vapor deposition (PVD) (e.g., sputtering), thermal oxidation, and/or another suitable deposition technique. A deposition tool may be used to form the fin patterning layer 110 using a CVD technique, an ALD technique, an epitaxy technique (e.g., molecular beam epitaxy (MBE) and/or another epitaxy technique), and/or another suitable deposition technique.

Turning to FIGS. 1C and 1D, portions of the substrate 104 for the semiconductor device 102 may be removed to form various active regions in the substrate 104. FIG. 1C illustrates a perspective view of the semiconductor device 102, and FIG. 1D illustrates a cross-section view of the semiconductor device 102 along the line A-A in FIG. 1C.

As shown in FIG. 1C, the active regions may be formed in a low voltage transistor region 112 and a medium voltage transistor region 114 adjacent to the low voltage transistor region 112. In some implementations, active regions are also formed in a high voltage transistor region 116 that may be adjacent to the medium voltage transistor region 114, or may be located in another region of the semiconductor device 102. The active regions formed in the low voltage transistor region 112 include fin-shaped active regions 118. The fin-shaped active regions 118 may be formed for low voltage transistor structures that are to be formed in the low voltage transistor region 112. The low voltage transistor structures may include fin-based transistor structures. The fin-shaped active regions 118 may extend in an x-direction in the semiconductor device 102 and may be arranged in a y-direction in the semiconductor device 102. The fin-shaped active regions 118 may extend above the substrate 104 in the z-direction in the semiconductor device 102.

As further shown in FIG. 1C, the active regions formed in the medium voltage transistor region 114 include planar active regions 120. The planar active regions 120 may be formed for medium voltage transistor structures that are to be formed in the medium voltage transistor region 114. The medium voltage transistor structures may include planar transistor structures. Additionally and/or alternatively, fin-shaped active regions may be formed for one or more fin-based medium voltage transistor structures in the medium voltage transistor region 114. The planar active regions 120 may extend in the x-direction in the semiconductor device 102 and may be arranged in the y-direction in the semiconductor device 102. The planar active regions 120 may extend above the substrate 104 in the z-direction in the semiconductor device 102.

A planar active region 120 may have a greater y-direction width than a y-direction width of a fin-shaped active region 118. Additionally and/or alternatively, the y-direction spacing between adjacent planar active regions 120 in the medium voltage transistor region 114 may be greater than the y-direction spacing between adjacent fin-shaped active regions 118 in the low voltage transistor region 112.

As further shown in FIG. 1C, the active regions formed in the high voltage transistor region 116 include planar active regions 122. The planar active regions 122 may be formed for high voltage transistor structures that are to be formed in the high voltage transistor region 116. The high voltage transistor structures may include planar transistor structures. Additionally and/or alternatively, fin-shaped active regions may be formed for one or more fin-based high voltage transistor structures in the high voltage transistor region 116. The planar active regions 122 may extend in the x-direction in the semiconductor device 102 and may be arranged in the y-direction in the semiconductor device 102. The planar active regions 122 may extend above the substrate 104 in the z-direction in the semiconductor device 102.

In some implementations, a y-direction width of a planar active region 122 is greater than a y-direction width of a planar active region 120. In some implementations, a y-direction width of a planar active region 120 is greater than a y-direction width of a planar active region 122. In some implementations, a y-direction width of a planar active region 120 and a y-direction width of a planar active region 122 are approximately equal. In some implementations, the y-direction spacing between adjacent planar active regions 122 in the high voltage transistor region 116 is greater than the y-direction spacing between adjacent planar active regions 120 in the medium voltage transistor region 114. In some implementations, the y-direction spacing between adjacent planar active regions 120 in the medium voltage transistor region 114 is greater than the y-direction spacing between adjacent planar active regions 122 in the high voltage transistor region 116. In some implementations, the y-direction spacing between adjacent planar active regions 122 in the high voltage transistor region 116 and the y-direction spacing between adjacent planar active regions 120 in the medium voltage transistor region 114 are approximately equal.

The pad oxide layer 106, the hard mask layer 108 and/or the fin patterning layer 110 may be used for patterning the substrate 104 to form the fin-shaped active regions 118, the planar active regions 120, and/or the planar active regions 122 in the substrate 104. For example, the fin patterning layer 110 may be used to form a layer of mandrels above the substrate 104 so that the mandrels can be used to form spacers that are then used to etch the substrate 104 to form the fin-shaped active regions 118, the planar active regions 120, and/or the planar active regions 122. A pattern in a photoresist layer is used to form the mandrels in the fin patterning layer 110. A deposition tool may be used to form the photoresist layer on the fin patterning layer 110. An exposure tool may be used to expose the photoresist layer to a radiation source to pattern the photoresist layer. A developer tool may be used to develop and remove portions of the photoresist layer to expose the pattern. An etch tool may be used to etch the fin patterning layer 110 based on the pattern to form the mandrels. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). A deposition tool may be used to deposit a spacer layer over and around the mandrels, and an etch tool may be used to remove portions of the spacer layer to form the spacers on the hard mask layer 108. An etch tool may be used to etch through the hard mask layer 108, through the pad oxide layer 106, and into the substrate 104 to form the fin-shaped active regions 118, the planar active regions 120, and/or the planar active regions 122 in the substrate 104.

Other techniques may be used to form the fin-shaped active regions 118, the planar active regions 120, and/or the planar active regions 122 in the substrate 104. Such techniques may include double patterning techniques, triple patterning techniques, quadruple patterning techniques, self-aligned patterning techniques, and/or other patterning techniques.

As further shown in FIG. 1C, forming the fin-shaped active regions 118, the planar active regions 120, and the planar active regions 122 in the substrate 104 results in formation of one or more isolation recesses in the substrate 104. For example, forming the fin-shaped active regions 118 in the low voltage transistor region 112 and forming the planar active regions 120 in the medium voltage transistor region 114 results in formation of an isolation recess 124 between a fin-shaped active region 118 of the low voltage transistor region 112 and a planar active region 120 of the medium voltage transistor region 114. As another example, forming the planar active regions 120 in the medium voltage transistor region 114 results in formation of an isolation recess 126 between adjacent planar active regions 120 in the medium voltage transistor region 114. As another example, forming the planar active regions 120 in the medium voltage transistor region 114 and forming the planar active regions 122 in the high voltage transistor region 116 results in formation of an isolation recess 128 between a planar active region 120 in the medium voltage transistor region 114 and a planar active region 122 in the high voltage transistor region 116.

As shown in FIG. 1D, removing the portions of the substrate 104 results in formation of the isolation recess 124 such that the isolation recess 124 has a depth corresponding to a dimension D1. The depth of the isolation recess 124 is relative to the top surfaces of the planar active regions 120, and/or relative to the top surfaces of the fin-shaped active regions 118. Similarly, removing the portions of the substrate 104 results in formation of the isolation recess 126 such that the isolation recess 126 has a depth corresponding to the dimension D1. The depth of the isolation recess 126 is relative to the top surfaces of the planar active regions 120. Removing the portions of the substrate 104 results in formation of the isolation recess 128 such that the isolation recess 128 has a depth corresponding to the dimension D1. The depth of the isolation recess 128 is relative to the top surfaces of the planar active regions 120 and/or relative to the top surfaces of the planar active regions 122. Thus, the depths of the isolation recesses 124, 126, and 128 may be approximately equal.

Removing the portions of the substrate 104 results in formation of the fin-shaped active regions 118 such that the fin-shaped active regions 118 have a fin height corresponding to a dimension D2. The fin height of the fin-shaped active regions 118 may be relative to the bottom surface of the substrate 104 in the low voltage transistor region 112. In some implementations, the top surfaces of the fin-shaped active regions 118, the top surfaces of the planar active regions 120, and the top surfaces of the planar active regions 122 are approximately co-planar in the semiconductor device 102.

Turning to FIGS. 1E and 1F, one or more of the fin-shaped active regions 118 in the low voltage transistor region 112 of the semiconductor device 102 may be removed to form one or more fin cut regions 130 in the low voltage transistor region 112. FIG. 1E illustrates a perspective view of the semiconductor device 102, and FIG. 1F illustrates a cross-section view of the semiconductor device 102 along the line A-A in FIG. 1E.

As shown in FIG. 1E, a fin cut region 130 includes a portion of the low voltage transistor region 112 in which one or more fin-shaped active regions 118 have been removed. The fin cut region 130 may be adjacent to one or more of the fin-shaped active regions 118. In some implementations, a fin cut region 130 is located between subsets of fin-shaped active regions 118 in the low voltage transistor region 112 to provide electrical isolation for adjacent low voltage transistor structures that are to be formed in the low voltage transistor region 112. In some implementations, a fin cut region 130 is located between a fin-shaped active region 118 and the isolation recess 124, and is located between the fin-shaped active region 118 and a planar active region 120 of the medium voltage transistor region 114. The fin cut region(s) 130 may extend in the x-direction in the semiconductor device 102. Thus, the fin cut region(s) 130 extend in the same direction as (and approximately parallel to) the isolation recesses 124, 126, and/or 128, as well as extend in the same direction as the fin-shaped active regions 118.

A fin cut region 130 may be formed using a pattern in a photoresist layer to etch one or more fin-shaped active regions 118. A deposition tool may be used to form the photoresist layer on the fin-shaped active regions 118 in the low voltage transistor region 112. An exposure tool may be used to expose the photoresist layer to a radiation source to pattern the photoresist layer. A developer tool may be used to develop and remove portions of the photoresist layer to expose the pattern, where at least a subset of the fin-shaped active regions 118 are exposed through the pattern. An etch tool may be used to etch the at least the subset of the fin-shaped active regions 118 based on the pattern to remove the at least the subset of the fin-shaped active regions 118 to form the fin cut region 130. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 1F, the distance (dimension D3) between the top of a cut fin in a fin cut region 130 and a top of a fin-shaped active region 118 may be less than the fin height (dimension D2) of the fin-shaped active region 118. Thus, a cut fin may include a remaining portion of a fin-shaped active region 118 that was mostly removed to form the cut fin.

Turning to FIG. 1G, at least a subset of the fin-shaped active regions 118 in the low voltage transistor region 112 of the semiconductor device 102 are cut in the y-direction to form one or more fin cut regions 132 in the low voltage transistor region 112. FIG. 1G illustrates a perspective view of the semiconductor device 102.

As shown in FIG. 1G, a fin cut region 132 may extend in the y-direction across a plurality of fin-shaped active regions 118. The fin cut region 132 may be formed to form a plurality of sections of fin-shaped active regions 118 that are arranged in the x-direction in the semiconductor device 102. This enables sections of low voltage transistor structures to be electrically isolated in the x-direction in the low voltage transistor region 112. Fin cut regions 132 may be formed using similar patterning techniques as described above for forming the fin cut regions 130.

FIGS. 1H-1J illustrate a process for increasing the depth of the isolation recesses 124, 126, and 128. The process illustrated in FIGS. 1H-1J is part of a dual STI process (together with the operations described in connection with FIGS. 1C and 1D) to form the isolation recesses 124, 126, and 128 to an increased depth so that a greater amount of electrical isolation can be provided between the medium voltage transistor region 114 and other regions (e.g., the low voltage transistor region 112 adjacent to the medium voltage transistor region 114, the high voltage transistor region 116 adjacent to the medium voltage transistor region 114) in the semiconductor device 102.

As shown in a cross-section view in FIG. 1H, a masking layer 134 is formed over the semiconductor device 102, and the masking layer 134 is patterned to expose the isolation recesses 124, 126, and 128 through the masking layer 134. The masking layer 134 may remain on the fin-shaped active regions 118 in the low voltage transistor region 112 and on the planar active regions 122 in the high voltage transistor region 116 after patterning. The masking layer 134 may include a photoresist layer. To pattern the masking layer 134, a deposition tool may be used to form the masking layer 134 on the semiconductor device 102. An exposure tool may be used to expose the masking layer 134 to a radiation source to pattern the masking layer 134. A developer tool may be used to develop and remove portions of the masking layer 134 to expose the pattern, where the isolation recesses 124, 126, and 128, and the planar active regions 120, are exposed through the pattern. In some implementations, portions of the masking layer 134 cover portions of the isolation recess 124 and 128 to prevent undercutting of the planar active regions 122 and undercutting of the fin-shaped active regions 118 when etching the substrate 104 to increase the depth of the isolation recesses 124, 126, and 128.

An etch tool may be used to etch the at least the subset of the fin-shaped active regions 118 based on the pattern to remove the at least the subset of the fin-shaped active regions 118 to form the fin cut region 130. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in a cross-section view in FIG. 1I, additional material of the substrate 104 is removed from the bottom surfaces of the isolation recesses 124, 126, and 128 based on the pattern in the masking layer 134. The additional material of the substrate 104 is removed to increase the depth of the isolation recesses 124, 126, and 128. FIG. 1J illustrates a perspective view of the semiconductor device 102 after the depth of the isolation recesses 124, 126, and 128 is increased.

As shown in FIG. 1I, the depth of the isolation recesses 124, 126, and 128 may be increased from the dimension D1 to a dimension D4. The substrate 104 may be etched in the isolation recesses 124, 126, and 128 to increase the depth of the isolation recesses 124, 126, and 128. The etching consumes some of the portions of the hard mask layer 108 on the planar active regions 120 because the planar active regions 120 are exposed through the pattern in the masking layer 134 during the etching of the substrate 104. The hard mask layer 108 on the planar active regions 120 protects the planar active regions 120 from etching. As a result, a thickness of the hard mask layer 108 on the planar active regions 120 is less than a thickness of the hard mask layer 108 on the planar active regions 122 and on the fin-shaped active regions 118 because the planar active regions 122 and the fin-shaped active regions 118 were covered and protected by the masking layer 134 during the etching of the substrate 104.

The substrate 104 in the isolation recesses 124, 126, and 128 may be etched using a dry etch technique, a wet etch technique, a plasma-based etch technique, and/or another suitable etch technique. In some implementations, an oxygen-containing gas is used to control the respective etch rates of the material of the hard mask layer 108 and the material of the substrate 104 during the etch to increase the depth of the isolation recesses 124, 126, and 128. In particular, the oxygen-containing gas may be used to control the amount of the hard mask layer 108 that is consumed during the etch, and to control the amount of the substrate 104 that is removed during the etch. A flow rate, of the flow of the oxygen-containing gas that is provided into a processing chamber in which the semiconductor device 102 is positioned for the etch, may be controlled to be within a range of greater than 0 standard cubic centimeters per minute (sccm) and less than or approximately equal to 15 sccm. If the flow rate of the flow of the oxygen-containing gas is too low (e.g., is 0 sccm), the etch rate for the material of the hard mask layer 108 may be too high, and too much material may be removed from the hard mask layer 108 during the etch. If this occurs, an insufficient amount of the hard mask layer 108 may remain on the planar active regions 120 to sufficiently protect the planar active regions 120 in a subsequent planarization operation that is described below in connection with FIG. 1L. If the flow rate of the flow of the oxygen-containing gas is too high (e.g., greater than approximately 15 sccm), the etch rate for the material of the substrate 104 may be too low to sufficiently increase the depth of the isolation recesses 124, 126, and 128. As a result, insufficient electrical isolation may be provided for the medium voltage transistors in the medium voltage transistor region 114, resulting in an increased likelihood of current leakage from the medium voltage transistors degrading the performance of (and/or damaging) other transistors in the semiconductor device 102, such as the low voltage transistors in the low voltage transistor region 112. If the flow rate of the flow of the oxygen-containing gas is controlled within the range of greater than 0 sccm and less than or approximately equal to 15 sccm, sufficient etching of the substrate 104 may be achieved while ensuring that a sufficient amount of the hard mask layer 108 remains for subsequent processing operations. However, other values for the flow rate of the flow of the oxygen-containing gas, and ranges other than greater than 0 sccm and less than or approximately equal to 15 sccm, are within the scope of the present disclosure.

In some implementations, a post-etch cleaning of the isolation recesses 124, 126, and/or 128 is performed after etching the substrate 104 to increase the depth of the isolation recesses 124, 126, and/or 128. The post-etch cleaning may be performed to remove etch byproducts, to remove residual oxides, and/or to remove residual etchant from the isolation recesses 124, 126, and/or 128, among other examples.

As further shown in FIG. 1I, the isolation recess 124 may have portions that have different depths because of the masking layer 134 covering a portion of the isolation recess 124 during the etch to increase the depth of the isolation recess 124. For example, a portion 136 of the isolation recess 124 that was not covered by the masking layer 134 (e.g., the portion of the isolation recess 124 adjacent to a planar active region 120) has a depth corresponding to the dimension D4, and another portion 136 of the isolation recess 124 that was covered by the masking layer 134 (e.g., the portion of the isolation recess 124 adjacent to the low voltage transistor region 112) remains at the depth corresponding to the dimension D1. Thus, the bottom surface of the isolation recess 124 may have a stair-stepped cross-sectional profile. The dimension D1 may be included in a range of approximately 1,300 angstroms to approximately 1,700 angstroms, whereas the dimension D4 may be greater than 1,700 angstroms and less than or approximately equal to 10,000 angstroms. However, other values for these ranges are within the scope of the present disclosure.

Similarly, the isolation recess 128 may have portions that have different depths because of the masking layer 134 covering a portion of the isolation recess 128 during the etch to increase the depth of the isolation recess 128. For example, a portion 140 of the isolation recess 128 that was not covered by the masking layer 134 (e.g., the portion of the isolation recess 128 adjacent to a planar active region 120) has a depth corresponding to the dimension D4, and another portion 142 of the isolation recess 128 that was covered by the masking layer 134 (e.g., the portion of the isolation recess 128 adjacent to the high voltage transistor region 116) remains at the depth corresponding to the dimension D1. Thus, the bottom surface of the isolation recess 128 may have a stair-stepped cross-sectional profile.

As shown in a cross-section view in FIG. 1K, an isolation layer 144 is formed on the substrate 104. A deposition tool may be used to deposit the isolation layer 144 using a CVD technique, a PVD technique, an ALD technique, an oxidation technique, and/or another deposition technique. The isolation layer 144 fills in the isolation recesses 124, 126, and 128. The isolation layer 144 also fills in the spaces between the fin-shaped active regions 118, fills in the fin cut regions 130 over the cut fins, and fills in the fin cut region 132. The isolation layer 144 may include one or more dielectric materials, such as a silicon oxide (SiOₓ such as SiO₂), silicon oxynitride (SiON), silicon oxycarbide (SiOC), fluoride-doped silicate glass (FSG), undoped silicate glass (USG), a silicon nitride (SiₓN_{y} such as Si₃N₄), a silicon carbon nitride (SiCN), a silicon oxycarbonnitride (SiOCN), and/or another suitable dielectric nitride material.

As shown in FIG. 1K, the isolation layer 144 may be formed to a height that is greater than the height of the planar active regions 120 in the medium voltage transistor region 114, and that is greater than the height of the planar active regions 122 in the high voltage transistor region 116. In other words, the isolation layer 144 is formed such that the isolation layer 144 covers the planar active regions 120 and 122. In some implementations, the isolation layer 144 is formed such that the isolation layer 144 also covers the fin-shaped active regions 118, and an etch tool is used to etch a portion of the isolation layer 144 to reduce the height of the isolation layer 144 in the low voltage transistor region 112. In particular, the isolation layer 144 may be etched such that the top surface of the isolation layer 144 in the low voltage transistor region 112 is below the tops of the fin-shaped active regions 118. The isolation layer 144 may be etched using a plasma etch technique, a wet chemical etch technique, and/or another type of etch technique. The remaining portions of the isolation layer 144 between the fin-shaped active regions 118 may include STI regions between the fin-shaped active regions 118.

Alternatively, the isolation layer 144 may be deposited such that the top surface of the isolation layer 144 in the low voltage transistor region 112 is below the tops of the fin-shaped active regions 118. This may result in the top surface of the isolation layer 144 sloping downward from the medium voltage transistor region 114 to the low voltage transistor region 112.

As shown in a cross-section view in FIG. 1L, the isolation layer 144 may be planarized to remove excess material from the isolation layer 144. A planarization tool may be used to perform a planarization operation using a chemical mechanical planarization (CMP) technique and/or another suitable planarization technique to planarize the isolation layer 144. Removal of the excess material of the isolation layer 144 results in formation of cut fin isolation regions 146 (e.g., dielectric isolation regions) in the fin cut regions 130 adjacent to the fin-shaped active regions. The cut fin isolation regions 146 may have a thickness (dimension D5) on the bottom surface of the substrate 104 in the low voltage transistor region 112 and another thickness (dimension D6) on the cut fins in the low voltage transistor region 112. In some implementations, the dimension D5 and the dimension D6 are approximately a same value, resulting in the top surface of a cut fin isolation region 146 having different z-direction heights above the cut fins and above the substrate 104. In some implementations, the dimension D5 and the dimension D6 are approximately a same value in a cut fin isolation region 146, resulting in a substantially uniform z-direction height for the top surface of the cut fin isolation region 146.

As further shown in FIG. 1L, removal of the excess material of the isolation layer 144 results in formation of an isolation region 148 (e.g., a dielectric isolation region) between the medium voltage transistor region 114 and the low voltage transistor region 112. In particular, the isolation region 148 is included between a planar active region 120 of the medium voltage transistor region 114 and the fin-shaped active regions 118 in the low voltage transistor region 112. The isolation region 148 may be located between a cut fin isolation region 146 and the planar active region 120 of the medium voltage transistor region 114, and the cut fin isolation region 146 may be located between the isolation region 148 and the fin-shaped active regions 118 in the low voltage transistor region 112.

The isolation region 148 may be included to provide electrical isolation between medium voltage transistors included in the medium voltage transistor region 114 and the low voltage transistors included in the low voltage transistor region 112. The bottom surface of the isolation region 148 may have a stair-stepped profile such that the isolation region 148 includes a portion 154 and another portion 156 in which segments of the bottom surface of the isolation region 148 are at different z-direction heights in the semiconductor device 102. The different z-direction heights result from the dual STI technique, described in connection with FIGS. 1C, 1D, 1H, 1I, and 1J that was used to form the isolation recess 124. The portion 154 is adjacent to a planar active region 120 in the medium voltage transistor region 114, and the portion 156 is between the portion 154 and the plurality of fin-shaped active regions 118. The portion 156 may also be adjacent to a cut fin isolation region 146 in the low voltage transistor region 112.

The segment of the bottom surface of the isolation region 148 in the portion 154 is lower in the semiconductor device 102 than bottoms of the fin-shaped active regions 118, and is lower in the semiconductor device 102 that the segment of the bottom surface of the isolation region 148 in the portion 156. The segment of the bottom surface of the isolation region 148 in the portion 154 is also lower in the semiconductor device 102 than top surfaces of one or more cut fins in a fin cut region 130 in the low voltage transistor region 112.

The segment of the bottom surface of the isolation region 148 in the portion 156 is lower in the semiconductor device 102 than the bottoms of the fin-shaped active regions 118, but is higher in the semiconductor device 102 than the segment of the bottom surface of the isolation region 148 in the portion 154. The segment of the bottom surface of the isolation region 148 in the portion 156 is also lower in the semiconductor device 102 than top surfaces of one or more cut fins in a fin cut region 130 in the low voltage transistor region 112.

The portion 156 of the isolation region 148 has a thickness (dimension D7), and the portion 154 of the isolation region 148 has a thickness (dimension D8) that is greater than the thickness of the portion 156 of the isolation region 148. In some implementations, the thickness of the portion 154 (the dimension D8) is greater than approximately 1,700 angstroms and less than or approximately equal to 10,000 angstroms, which may enable sufficient electrical isolation between the medium voltage transistors in the medium voltage transistor region 114 and the low voltage transistors in the low voltage transistor region 112 to be achieved. However, other values for the range are within the scope of the present disclosure.

The greater thickness of the portion 154 of the isolation region 148 may result from the segment of the bottom surface of the isolation region 148 in the portion 154 being lower in the semiconductor device 102 than the segment of the bottom surface of the isolation region 148 in the portion 156, and/or may result from the top surface of the isolation region 148 in the portion 154 being at a higher z-direction position in the semiconductor device 102 than the z-direction position of the top surface of the isolation region 148 in the portion 156. The difference (dimension D9) in z-direction position of the top surface of the isolation region 148 across the isolation region 148 results in the top surface being downwardly sloped from the portion 154 to the portion 156. The downward slope of the top surface of the isolation region 148 may result from the top surface of the isolation layer 144 sloping downward from the medium voltage transistor region 114 to the low voltage transistor region 112. Thus, the thickness of the isolation region 148 may decrease from the planar active region 120 to the fin-shaped active regions 118.

As further shown in FIG. 1L, removal of the excess material of the isolation layer 144 results in formation of an isolation region 150 (e.g., a dielectric isolation region) between adjacent planar active regions 120 in the medium voltage transistor region 114. The isolation region 150 was formed in the isolation recess 126 and may have an approximately uniform bottom surface. The isolation region 150 may have a thickness corresponding to the dimension D8. The isolation region 150 may be included to provide electrical isolation between adjacent medium voltage transistors included in the medium voltage transistor region 114.

As further shown in FIG. 1L, removal of the excess material of the isolation layer 144 results in formation of an isolation region 152 (e.g., a dielectric isolation region) between the medium voltage transistor region 114 and the high voltage transistor region 116. In particular, the isolation region 152 is included between a planar active region 120 of the medium voltage transistor region 114 and a planar active region 122 in the high voltage transistor region 116. The isolation region 152 may be included to provide electrical isolation between medium voltage transistors included in the medium voltage transistor region 114 and the high voltage transistors included in the high voltage transistor region 116.

The bottom surface of the isolation region 152 may have a stair-stepped profile such that the isolation region 152 includes a portion 158 and another portion 160 in which segments of the bottom surface of the isolation region 152 are at different z-direction heights in the semiconductor device 102. The different z-direction heights result from the dual STI technique, described in connection with FIGS. 1C, 1D, 1H, 1I, and 1J that was used to form the isolation recess 128 in which the isolation region 152 was formed. The portion 158 is adjacent to a planar active region 120 in the medium voltage transistor region 114, and the portion 160 is between the portion 158 and a planar active region 122 of the high voltage transistor region 116.

The segment of the bottom surface of the isolation region 152 in the portion 158 is lower in the semiconductor device 102 than bottoms of the fin-shaped active regions 118, and is lower in the semiconductor device 102 that the segment of the bottom surface of the isolation region 152 in the portion 160. The segment of the bottom surface of the isolation region 152 in the portion 158 is also lower in the semiconductor device 102 than top surfaces of one or more cut fins in a fin cut region 130 in the low voltage transistor region 112. The segment of the bottom surface of the isolation region 152 in the portion 158 may be at approximately a same height in the semiconductor device 102 as the portion 154 of the isolation region 148.

The segment of the bottom surface of the isolation region 152 in the portion 160 is lower in the semiconductor device 102 than the bottoms of the fin-shaped active regions 118, but is higher in the semiconductor device 102 than the segment of the bottom surface of the isolation region 152 in the portion 158. The segment of the bottom surface of the isolation region 152 in the portion 160 is also lower in the semiconductor device 102 than top surfaces of one or more cut fins in a fin cut region 130 in the low voltage transistor region 112. The segment of the bottom surface of the isolation region 152 in the portion 160 may be at approximately a same height in the semiconductor device 102 as the portion 156 of the isolation region 148.

The portion 160 of the isolation region 152 has a thickness (dimension D7), and the portion 158 of the isolation region 152 has a thickness (dimension D8) that is greater than the thickness of the portion 160 of the isolation region 152. In some implementations, the thickness of the portion 158 (the dimension D8) is greater than approximately 1,700 angstroms and less than or approximately equal to 10,000 angstroms, which may enable sufficient electrical isolation between the medium voltage transistors in the medium voltage transistor region 114 and the high voltage transistors in the high voltage transistor region 116 to be achieved. However, other values for the range are within the scope of the present disclosure.

As further shown in FIG. 1L, the pad oxide layer 106 and the hard mask layer 108 are also removed during the planarization operation. The pad oxide layer 106 and the hard mask layer 108 protect the tops of the fin-shaped active regions 118, the tops of the planar active regions 120, and the tops of the planar active regions 120 during the planarization operation. Moreover, the pad oxide layer 106 and the hard mask layer 108 may provide an etch stop indication for stopping the planarization operation. In other words, the pad oxide layer 106 and the hard mask layer 108 being fully removed provides an indication to stop the planarization operation.

As indicated above, FIGS. 1A-1L are provided as an example. Other examples may differ from what is described with regard to FIGS. 1A-1L.

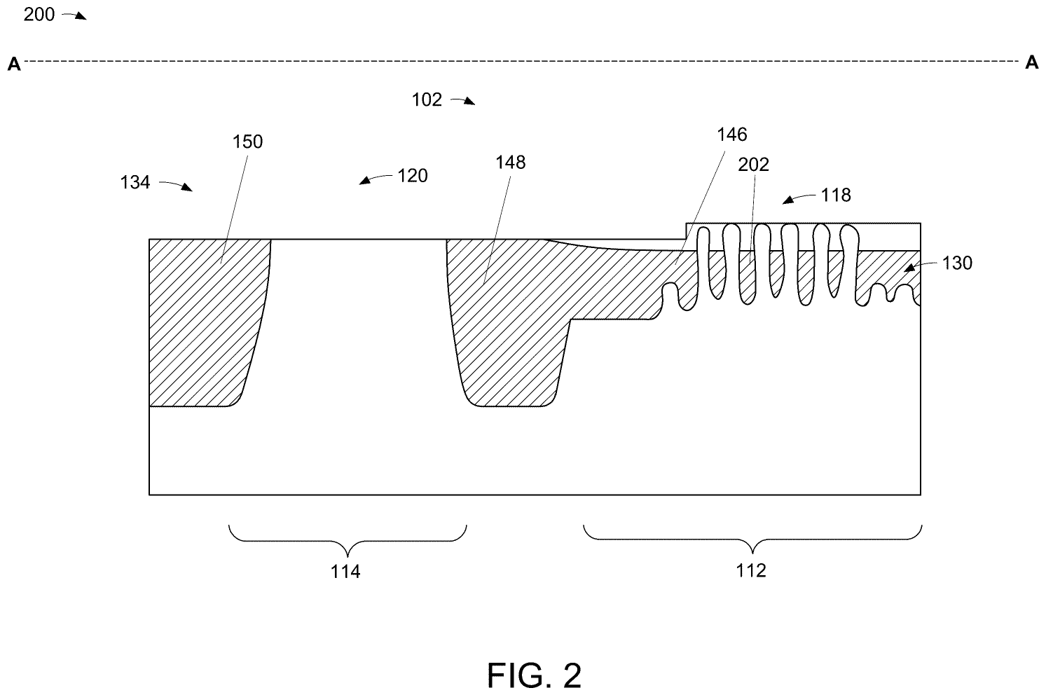

FIG. 2 is a diagram of an example 200 of the semiconductor device 102 described herein. FIG. 2 illustrates a cross-section view of the example 200 of the semiconductor device 102 along the line A-A. The example 200 includes an example of the semiconductor device 102 after formation of the isolation regions 148 and 150, and after formation of the cut fin isolation regions 146 described in connection with FIGS. 1A-1L. As shown in FIG. 2, the planar active region 120 in the medium voltage transistor region 114 may have outwardly sloped sidewalls from a top of the planar active region 120 to the bottom of the planar active region 120. This results in the isolation regions 148 and 150 having inwardly tapered sidewalls from the tops of the isolation regions 148 and 150 to the bottoms of the isolation regions 148 and 150. Moreover, the top surface of the isolation region 148 may be downwardly sloped from the planar active region 120 to a cut fin isolation region 146 adjacent to the isolation region 148. The fin-shaped active regions 118 may extend above the top surface of STI regions 202 between adjacent fin-shaped active regions 118.

As indicated above, FIG. 2 is provided as an example. Other examples may differ from what is described with regard to FIG. 2.

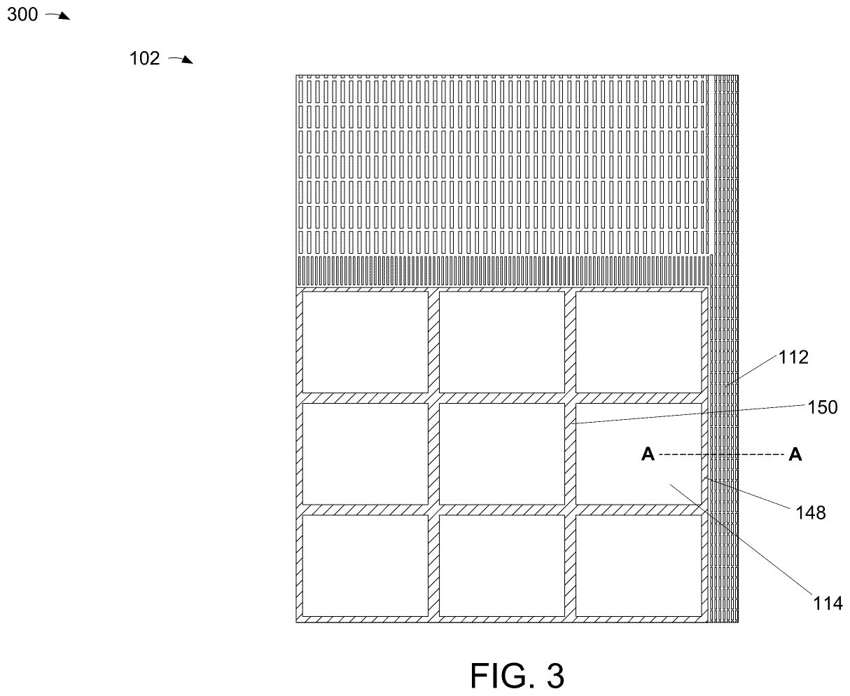

FIG. 3 is a diagram of an example 300 of the semiconductor device 102 described herein. FIG. 3 illustrates a top view (e.g., a layout view) of the example 300 of the semiconductor device 102. Thus, the example 300 in FIG. 3 includes an example of a layout of one or more regions of the semiconductor device 102, and illustrates an example location of the line A-A cross section in the layout of semiconductor device 102. However, other examples of layouts for the semiconductor device 102 are within the scope of the present disclosure.

As shown in FIG. 3, a low voltage transistor region 112 may be adjacent to a medium voltage transistor region 114 in the layout of the semiconductor device 102. Various isolation regions may be included between and/or around these regions to provide electrical isolation in the semiconductor device 102. For example, an isolation region 148 may be included between the medium voltage transistor region 114 and the low voltage transistor region 112. As another example, an isolation region 150 may be included between adjacent medium voltage transistor regions 114 and/or between planar active regions 120 within a medium voltage transistor region 114.

The isolation regions 148 and 150 may be formed using techniques described in connection with FIGS. 1A-1L to enable sufficient electrical isolation to be provided between the LDMOS transistors in the medium voltage transistor region 114 and the fin-based transistors in the low voltage transistor region 112.

As indicated above, FIG. 3 is provided as an example. Other examples may differ from what is described with regard to FIG. 3.

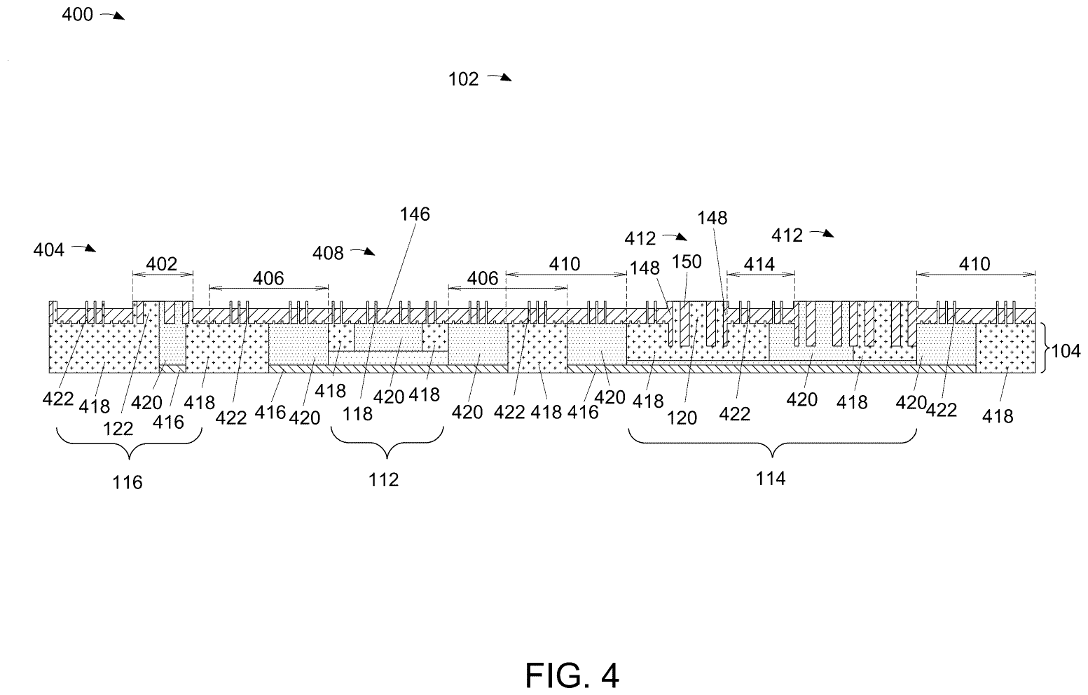

FIG. 4 is a diagram of an example 400 of the semiconductor device 102 described herein. FIG. 4 illustrates a cross-section view of the example 400 of the semiconductor device 102, and may include an example cross-section view of a portion of the example layout illustrated in FIG. 3.

As shown in FIG. 4, in the example 400, the semiconductor device 102 may include a low voltage transistor region 112, a medium voltage transistor region 114, and a high voltage transistor region 116. The high voltage transistor region 116 may include a device region 402 and a dummy region 404. The planar active regions 122 may be included in the device region 402 for high voltage transistors of the high voltage transistor region 116.

The low voltage transistor region 112 may be adjacent to the high voltage transistor region 116. The low voltage transistor region 112 and the high voltage transistor region 116 may be separated and electrically isolated by a low voltage isolation ring 406. The low voltage transistor region 112 may include fin-shaped active regions 118 for fin-based low voltage transistors in a device region 408. The low voltage transistor region 112 may also include dummy fins to enable various fin-spacing design rules to be satisfied in the layout of the semiconductor device 102.

The low voltage transistor region 112 may be adjacent to the medium voltage transistor region 114. The low voltage transistor region 112 and the medium voltage transistor region 114 may be separated and electrically isolated by the low voltage isolation ring 406 and by a medium voltage isolation ring 410. The medium voltage transistor region 114 may include a device region 412 in which the planar active regions 120 are provided for the medium voltage transistors of the medium voltage transistor region 114. A dummy region 414 may be provided within the medium voltage isolation ring 410.

As further shown in FIG. 4, the substrate 104 may include a plurality of doped regions, such as one or more deep n-well regions 416, one or more p-well regions 418, and one or more n-well regions 420. One or more of the regions 416, 418, and 420 may be included in the low voltage transistor region 112, the medium voltage transistor region 114, and/or in the high voltage transistor region 116. Dummy fins 422 may be included in the dummy regions 404 and/or 414 to enable various fin-spacing design rules to be satisfied in the layout of the semiconductor device 102.

As further shown in FIG. 4, various isolation regions may be included above the substrate 104. For example, one or more cut fin isolation regions 146 may be included in the device regions 402 and/or 408. As another example, one or more cut fin isolation regions 146 may be included in the dummy regions 404 and/or 414. As another example, one or more cut fin isolation regions 146 may be included in the low voltage isolation ring 406 and/or in the medium voltage isolation ring 410. As another example, one or more isolation regions 148 may be included between a planar active region 120 in the device region 412 of the medium voltage transistor region 114 and fin-shaped active regions 118 in the low voltage transistor region 112. As another example, isolation regions 150 may be included between adjacent planar active regions 120 in the device region 412 of the medium voltage transistor region 114.

As indicated above, FIG. 4 is provided as an example. Other examples may differ from what is described with regard to FIG. 4.

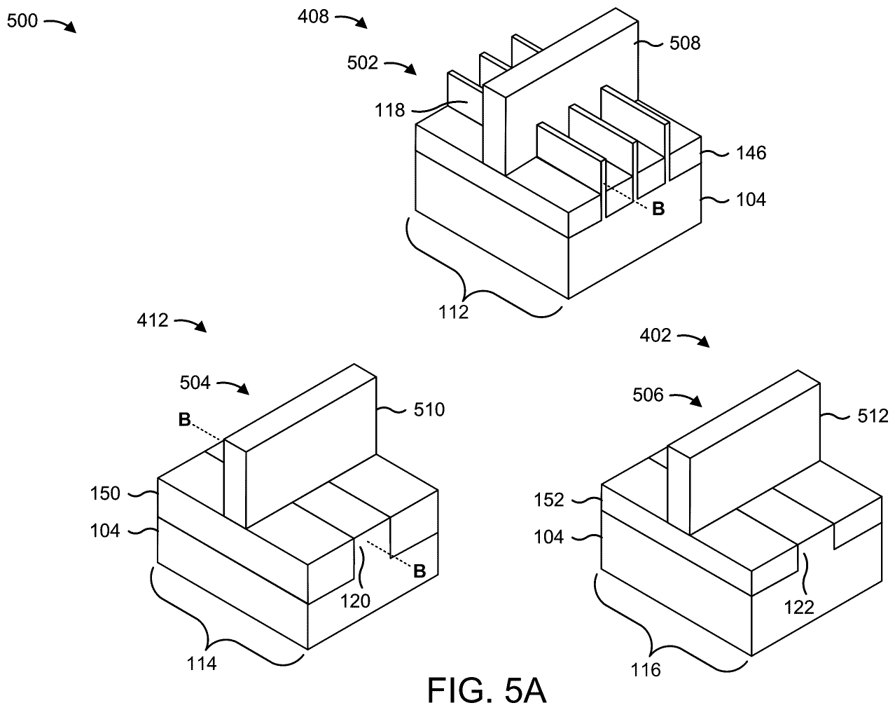

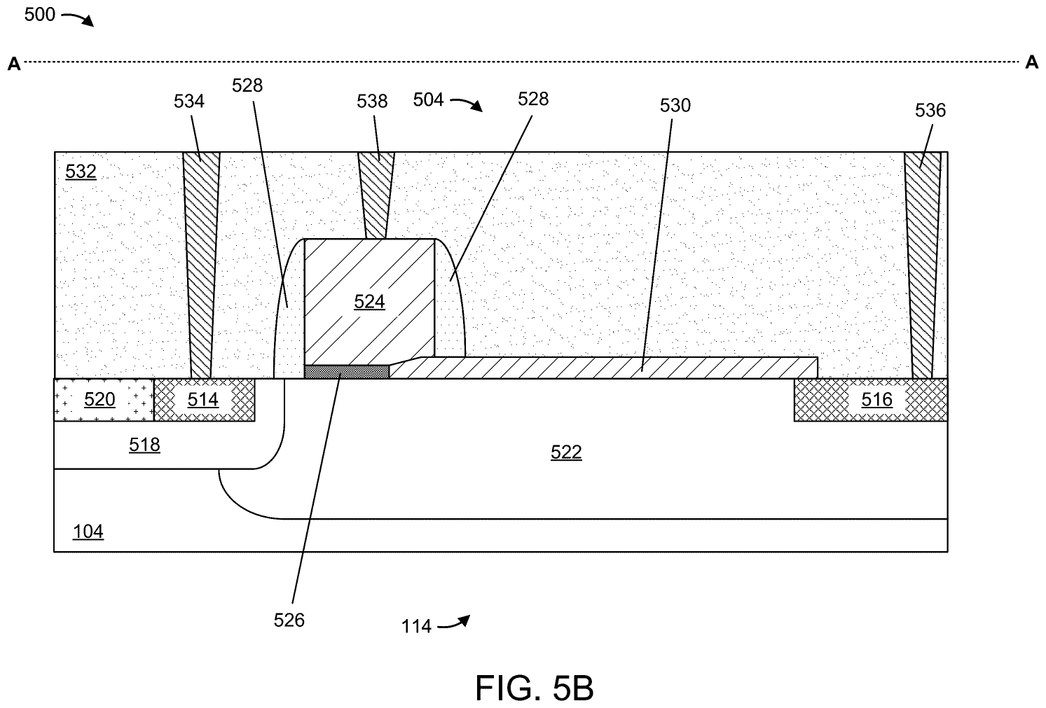

FIGS. 5A and 5B are diagrams of examples 500 of transistor structures for various types of transistors that may be included in the semiconductor device 102 described herein. As shown in FIG. 5A, an example low voltage transistor structure 502 may be included in a device region 408 of a low voltage transistor region 112 of the semiconductor device. The low voltage transistor structure 502 may be a fin-based transistor structure that includes one or more fin-shaped active regions 118 that are electrically isolated by STI regions and/or cut fin isolation regions 146.

As further shown in FIG. 5A, an example medium voltage transistor structure 504 may be included in a device region 412 of a medium voltage transistor region 114 of the semiconductor device 102. The medium voltage transistor structure 504 may be a planar transistor structure that includes a planar active region 120 that is electrically isolated by isolation regions 150. Additionally and/or alternatively, an isolation region 148 may be provided between the medium voltage transistor structure 504 and the low voltage transistor structure 502 in the semiconductor device 102.

As further shown in FIG. 5A, an example high voltage transistor structure 506 may be included in a device region 402 of a high voltage transistor region 116 of the semiconductor device 102. The high voltage transistor structure 506 may be a planar transistor structure that includes a planar active region 122 that is electrically isolated by isolation regions 152.

As further shown in FIG. 5A, the low voltage transistor structure 502 may include a gate structure 508 that wraps around at least three sides of the fin-shaped active regions 118. The medium voltage transistor structure 504 includes a planar gate structure 510 that extends over the top of the planar active region 120 and over the tops of the isolation regions 150. The high voltage transistor structure 506 may similarly include a planar gate structure 512 that extends over the top of the planar active region 122 and over the tops of the isolation regions 152.

FIG. 5B illustrates an example of the medium voltage transistor structure 504. The medium voltage transistor structure 504 may include an LDMOS transistor and/or another type of medium voltage transistor structure. As shown in FIG. 5B, the medium voltage transistor structure 504 may include a source/drain region 514 in the substrate 104, and a source/drain region 516 included in the substrate 104 of the semiconductor device 102. In some implementations, the source/drain region 514 is a source region of the medium voltage transistor structure 504, and the source/drain region 516 is a drain region of the medium voltage transistor structure 504 that is configured to operate at a medium voltage. The source/drain region 514 may be included in and/or above a doped body region 518 in the substrate 104 along with a body contact 520. The source/drain region 516 may be included in and/or above a drift region 522 in the substrate 104. The drift region 522 may include a region of the substrate 104 with low doping concentration (e.g., relative to the doped body region 518 and other doped regions) to enable the drift region 522 to accommodate the medium voltages of the medium voltage transistor structure 504.

A gate structure 524 may be included above the substrate 104 between the source/drain regions 514 and 516, and a gate dielectric layer 526 may be included between the gate structure 524 and the substrate 104. Sidewall spacers 528 may be included on the sidewalls of the gate structure 524. A voltage may be selectively applied to the gate structure 524 to selectively control the conductivity in the drift region 522 between the source/drain regions 514 and 516.

A field plate layer 530 may be included to increase the performance of the medium voltage transistor structure 504 by manipulating the electric field in the drift region 522. The field plate layer 530 may be shorted to the gate structure 524, may be shorted to the source/drain region 516, and/or may be electrically connected to another structure in the medium voltage transistor structure 504. A bias voltage may be applied to the field plate layer 530 through a field plate contact to reduce the peak electric field strength generated by the gate structure 524 in the drift region 522. This is referred to as a reduced surface field (RESURF) technique. The bias voltage increases carrier depletion in the drift region 522, thereby reducing the peak electric field strength in the drift region 522. By manipulating the electric field generated by the gate structure 524, the medium voltage transistor structure 504 can achieve increased breakdown voltages. In some implementations, a dielectric layer may be included between the substrate 104 and the field plate layer 530. The dielectric layer may be referred to as a local oxidation of silicon (LOCOS) layer and/or another type of dielectric layer.

As further shown in FIG. 5B, a dielectric layer 532 may be included over the medium voltage transistor structure 504. A source/drain contact 534 may be included in the dielectric layer 532 and may be electrically connected and/or physically connected with the source/drain region 514. A source/drain contact 536 may be included in the dielectric layer 532 and may be electrically connected and/or physically connected with the source/drain region 516. A gate contact 538 may be included in the dielectric layer 532 and may be electrically connected and/or physically connected with the gate structure 524.

As indicated above, FIGS. 5A and 5B are provided as an example. Other examples may differ from what is described with regard to FIGS. 5A and 5B.

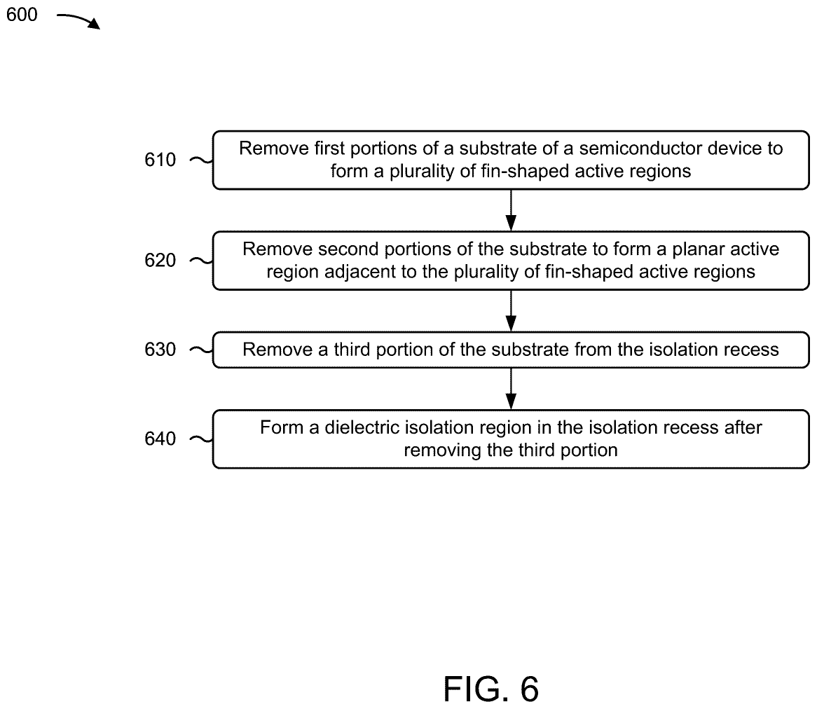

FIG. 6 is a flowchart of an example process 600 associated with forming a semiconductor device described herein. In some implementations, one or more process blocks of FIG. 6 are performed using one or more semiconductor processing tools, such as a deposition tool, an exposure tool, a developer tool, an etch tool, a planarization tool, an ion implantation tool, and/or a wafer/die transport tool, among other examples.

As shown in FIG. 6, process 600 may include removing first portions of a substrate of a semiconductor device to form a plurality of fin-shaped active regions (block 610). For example, one or more semiconductor processing tools may be used to remove first portions of a substrate 104 of a semiconductor device 102 to form a plurality of fin-shaped active regions 118, as described herein.

As further shown in FIG. 6, process 600 may include removing second portions of the substrate to form a planar active region adjacent to the plurality of fin-shaped active regions (block 620). For example, one or more semiconductor processing tools may be used to remove second portions of the substrate 104 to form a planar active region 120 adjacent to the plurality of fin-shaped active regions 118, as described herein. In some implementations, removing the second portions of the substrate 104 results in formation of an isolation recess 124 between the planar active region 120 and the plurality of fin-shaped active regions 118. In some implementations, the isolation recess 124 has a first depth (dimension D1), relative to a top of the planar active region 120, after removing the second portions of the substrate 104.

As further shown in FIG. 6, process 600 may include removing a third portion of the substrate from the isolation recess (block 630). For example, one or more semiconductor processing tools may be used to remove a third portion of the substrate 104 from the isolation recess 124, as described herein. The isolation recess 124 has a second depth (dimension D4), relative to the top of the planar active region 120, after the third portion of the substrate 104 is removed, and the second depth is greater than the first depth.

As further shown in FIG. 6, process 600 may include forming a dielectric isolation region in the isolation recess after removing the third portion (block 640). For example, one or more semiconductor processing tools may be used to form a dielectric isolation region (e.g., an isolation region 148) in the isolation recess 124 after removing the third portion, as described herein.

Process 600 may include additional implementations, such as any single implementation or any combination of implementations described below and/or in connection with one or more other processes described elsewhere herein.

In a first implementation, removing the third portion of the substrate 104 from the isolation recess 124 includes removing the third portion of the substrate 104 from the isolation recess 124 while the plurality of fin-shaped active regions 118 are covered by a masking layer 134.

In a second implementation, alone or in combination with the first implementation, the masking layer 134 covers a first portion (e.g., a portion 138) of a bottom surface of the isolation recess 124, and removing the third portion of the substrate 104 from the isolation recess 124 includes removing, while the masking layer 134 covers the first portion of the bottom surface of the isolation recess 124, the third portion of the substrate 104 from a second portion (e.g., portion 136) of the bottom surface of the isolation recess 124 adjacent to the first portion.

In a third implementation, alone or in combination with one or more of the first and second implementations, the first portion (e.g., the portion 138) of the bottom surface of the isolation recess 124 is at the first depth (the dimension D1), relative to the top of the planar active region 120, after the third portion of the substrate 104 is removed, and the second portion (e.g., the portion 136) of the bottom surface of the isolation recess 124 is at the second depth (the dimension D4), relative to the top of the planar active region 120, after removing the third portion of the substrate 104.

In a fourth implementation, alone or in combination with one or more of the first through third implementations, removing the third portion of the substrate 104 from the isolation recess 124 includes removing the third portion of the substrate 104 from the isolation recess 124 after forming a fin cut region 130 adjacent to the plurality of fin-shaped active regions 118, where the fin cut region 130 extends alongside the isolation recess 124.

In a fifth implementation, alone or in combination with one or more of the first through fourth implementations, process 600 includes performing a post-etch cleaning of the isolation recess 124 after removing the third portion of the substrate 104 from the isolation recess 124.

In a sixth implementation, alone or in combination with one or more of the first through fifth implementations, removing the third portion of the substrate 104 from the isolation recess 124 includes removing the third portion of the substrate 104 from the isolation recess 124 after forming a fin cut region 132 across the plurality of fin-shaped active regions 118, where the fin cut region 132 extends in a direction (e.g., the y-direction) that is approximately perpendicular to the isolation recess 124.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

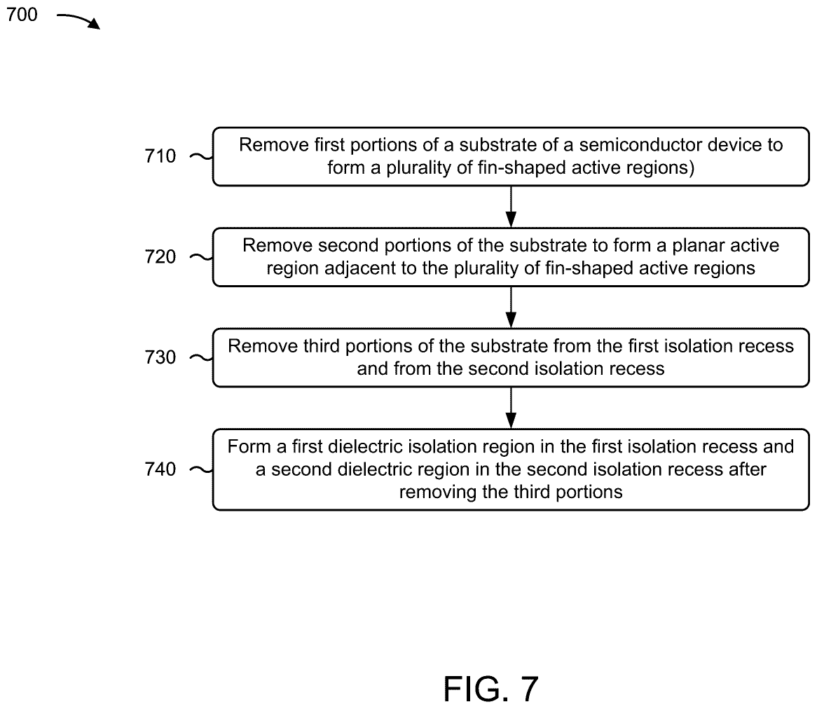

FIG. 7 is a flowchart of an example process 700 associated with forming a semiconductor device described herein. In some implementations, one or more process blocks of FIG. 6 are performed using one or more semiconductor processing tools, such as a deposition tool, an exposure tool, a developer tool, an etch tool, a planarization tool, an ion implantation tool, and/or a wafer/die transport tool, among other examples.

As shown in FIG. 7, process 700 may include removing first portions of a substrate of a semiconductor device to form a plurality of fin-shaped active regions (block 710). For example, one or more semiconductor processing tools may be used to remove first portions of a substrate 104 of a semiconductor device 102 to form a plurality of fin-shaped active regions 118, as described herein.

As further shown in FIG. 7, process 700 may include removing second portions of the substrate to form a planar active region adjacent to the plurality of fin-shaped active regions (block 720). For example, one or more semiconductor processing tools may be used to remove second portions of the substrate 104 to form a planar active region 120 adjacent to the plurality of fin-shaped active regions 118, as described herein. In some implementations, removing the second portions of the substrate 104 results in formation of a first isolation recess 124 between a first side of the planar active region 120 and the plurality of fin-shaped active regions 118, and a second isolation recess 126 adjacent to a second side of the planar active region 120 opposing the first side. In some implementations, a bottom surface of the first isolation recess 124 is at a first depth (dimension D1), relative to a top of the planar active region 120, after removing the second portions of the substrate 104. In some implementations, a bottom surface of the second isolation recess 126 is at the first depth (dimension D1), relative to the top of the planar active region 120, after removing the second portions of the substrate 104. In some implementations, the first depth is greater than a fin height (dimension D2) of the plurality of fin-shaped active regions 118.

As further shown in FIG. 7, process 700 may include removing third portions of the substrate from the first isolation recess and from the second isolation recess (block 730). For example, one or more semiconductor processing tools may be used to remove third portions of the substrate 104 from the first isolation recess 124 and from the second isolation recess 126, as described herein. In some implementations, at least a portion of the bottom surface of first isolation recess 124 is at a second depth (dimension D4), relative to the top of the planar active region 120, after removing the third portions of the substrate 104. In some implementations, the bottom surface of second isolation recess 126 is at the second depth (dimension D4), relative to the top of the planar active region 120, after removing the third portions of the substrate 104. In some implementations, the second depth is greater than the first depth.

As further shown in FIG. 7, process 700 may include forming a first dielectric isolation region in the first isolation recess and a second dielectric region in the second isolation recess after removing the third portions (block 740). For example, one or more semiconductor processing tools may be used to form a first dielectric isolation region (e.g., an isolation region 148) in the first isolation recess 124 and a second dielectric region (e.g., an isolation region 150) in the second isolation recess 126 after removing the third portions, as described herein.

Process 700 may include additional implementations, such as any single implementation or any combination of implementations described below and/or in connection with one or more other processes described elsewhere herein.

In a first implementation, another portion of the bottom surface of the first isolation recess 124, in a stepped section (e.g., portion 138) of the first isolation recess 124, is at the first depth (dimension D1) after removing the third portions of the substrate 104.

In a second implementation, alone or in combination with the first implementation, the stepped section (e.g., the portion 138) of the first isolation recess 124 is covered by a masking layer 134 while the third portions of the substrate 104 are removed from the first isolation recess 124 and from the second isolation recess 126.

In a third implementation, alone or in combination with one or more of the first and second implementations, a first thickness of a hard mask layer 108 on the top of the planar active region 120 is less than a second thickness of the hard mask layer 108 on the tops of the plurality of fin-shaped active regions 118 after removing the third portions of the substrate 104.

In a fourth implementation, alone or in combination with one or more of the first through third implementations, removing third portions of the substrate 104 from the first isolation recess 124 and from the second isolation recess 126 includes performing an etch operation to etch the substrate 104 to remove the third portions of the substrate 104 from the first isolation recess 124 and from the second isolation recess 126, where an oxygen-containing gas is used to control an etch selectivity between the substrate 104 and the hard mask layer 108.

In a fifth implementation, alone or in combination with one or more of the first through fourth implementations, a flow rate of the oxygen-containing gas in the etch operation is greater than 0 sccm and less than or approximately equal to 15 sccm.

In a sixth implementation, alone or in combination with one or more of the first through fifth implementations, forming the first dielectric isolation region and the second dielectric region includes depositing a dielectric layer (e.g., an isolation layer 144) in the first isolation recess 124 and in the second isolation recess 126, where the dielectric layer covers the planar active region 120, and performing a planarization operation on the dielectric layer to remove the dielectric layer from the planar active region 120, where the planarization operation results in formation of the first dielectric isolation region 148 and the second dielectric region 150.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a semiconductor device is formed such that isolation regions between a medium voltage transistor region and a low voltage transistor region are manufactured to have different properties than isolation regions between low voltage transistors in the low voltage transistor region. A dual STI technique described herein is used to form the isolation regions between the low voltage transistors in the low voltage transistor region using low voltage transistor isolation design rules, and additional STI formation operations may be performed to form the isolation regions between the low voltage transistor region and the medium voltage transistor region. In particular, the dual STI technique described herein may be used to form the isolation regions between the low voltage transistor region and the medium voltage transistor region such that these isolation regions are deeper than other isolation regions in the semiconductor device. This enables medium voltage transistors in the medium voltage transistor region to be positioned closer to the low voltage transistors in the low voltage transistor region with minimal to no increase in likelihood of current leakage from the medium voltage transistors impacting the performance of the low voltage transistors and/or damaging the low voltage transistors. Thus, the dual STI technique described herein may enable increased device density to be achieved in a semiconductor device that includes high voltage transistors, medium voltage transistors, and low voltage transistors.

As described in greater detail above, some implementations described herein provide a method. The method includes removing first portions of a substrate of a semiconductor device to form a plurality of fin-shaped active regions. The method includes removing second portions of the substrate to form a planar active region adjacent to the plurality of fin-shaped active regions, where removing the second portions of the substrate results in formation of an isolation recess between the planar active region and the plurality of fin-shaped active regions, and where the isolation recess has a first depth, relative to a top of the planar active region, after removing the second portions of the substrate. The method includes removing a third portion of the substrate from the isolation recess, where the isolation recess has a second depth, relative to the top of the planar active region, after removing the third portion of the substrate, and where the second depth is greater than the first depth. The method includes forming a dielectric isolation region in the isolation recess after removing the third portion.

As described in greater detail above, some implementations described herein provide a method. The method includes removing first portions of a substrate of a semiconductor device to form a plurality of fin-shaped active regions. The method includes removing second portions of the substrate to form a planar active region adjacent to the plurality of fin-shaped active regions, where removing the second portions of the substrate results in formation of a first isolation recess between a first side of the planar active region and the plurality of fin-shaped active regions, and a second isolation recess adjacent to a second side of the planar active region opposing the first side, where a bottom surface of the first isolation recess is at a first depth, relative to a top of the planar active region, after removing the second portions of the substrate, where a bottom surface of the second isolation recess is at the first depth, relative to the top of the planar active region, after removing the second portions of the substrate, and where the first depth is greater than a fin height of the plurality of fin-shaped active regions. The method includes removing third portions of the substrate from the first isolation recess and from the second isolation recess, where at least a portion of the bottom surface of first isolation recess is at a second depth, relative to the top of the planar active region, after removing the third portions of the substrate, where the bottom surface of second isolation recess is at the second depth, relative to the top of the planar active region, after removing the third portions of the substrate, and where the second depth is greater than the first depth. The method includes forming a first dielectric isolation region in the first isolation recess and a second dielectric region in the second isolation recess after removing the third portions.

As described in greater detail above, some implementations described herein provide a semiconductor device. The semiconductor device includes a plurality of fin-shaped active regions extending above a substrate of the semiconductor device. The semiconductor device includes one or more fin-based transistor structures on the plurality of fin-shaped active regions. The semiconductor device includes a planar active region extending above the substrate of the semiconductor device. The semiconductor device includes an LDMOS transistor structure on the planar active region. The semiconductor device includes a dielectric isolation region between the planar active region and the plurality of fin-shaped active regions, where the dielectric isolation region comprises: a first portion in which a bottom surface of the dielectric isolation region is lower in the semiconductor device than bottoms of the plurality of fin-shaped active regions a second portion in which the bottom surface of the dielectric isolation region is lower in the semiconductor device than the bottom surface of the dielectric isolation region in the first portion.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
removing first portions of a substrate of a semiconductor device to form a plurality of fin-shaped active regions;
removing second portions of the substrate to form a planar active region adjacent to the plurality of fin-shaped active regions,
wherein removing the second portions of the substrate results in formation of an isolation recess between the planar active region and the plurality of fin-shaped active regions, and
wherein the isolation recess has a first depth, relative to a top of the planar active region, after removing the second portions of the substrate;
removing a third portion of the substrate from the isolation recess,
wherein the isolation recess has a second depth, relative to the top of the planar active region, after removing the third portion of the substrate, and
wherein the second depth is greater than the first depth; and
forming a dielectric isolation region in the isolation recess after removing the third portion.

2. The method of claim 1, wherein removing the third portion of the substrate from the isolation recess comprises:
removing the third portion of the substrate from the isolation recess while the plurality of fin-shaped active regions are covered by a masking layer.

3. The method of claim 2, wherein the masking layer covers a first portion of a bottom surface of the isolation recess; and
wherein removing the third portion of the substrate from the isolation recess comprises:
removing, while the masking layer covers the first portion of the bottom surface of the isolation recess, the third portion of the substrate from a second portion of the bottom surface of the isolation recess adjacent to the first portion.

4. The method of claim 3, wherein the first portion of the bottom surface of the isolation recess is at the second depth, relative to the top of the planar active region, after the third portion of the substrate is removed; and
wherein the second portion of the bottom surface of the isolation recess is at the first depth, relative to the top of the planar active region, after removing the third portion of the substrate.

5. The method of claim 1, wherein removing the third portion of the substrate from the isolation recess comprises:
removing the third portion of the substrate from the isolation recess after forming a fin cut region adjacent to the plurality of fin-shaped active regions,
wherein the fin cut region extends alongside the isolation recess.

6. The method of claim 1, further comprising:
performing a post-etch cleaning of the isolation recess after removing the third portion of the substrate from the isolation recess.

7. The method of claim 1, wherein removing the third portion of the substrate from the isolation recess comprises:
removing the third portion of the substrate from the isolation recess after forming a fin cut region across the plurality of fin-shaped active regions,
wherein the fin cut region extends in a direction that is approximately perpendicular to the isolation recess.

8. A method, comprising:
removing first portions of a substrate of a semiconductor device to form a plurality of fin-shaped active regions,
removing second portions of the substrate to form a planar active region adjacent to the plurality of fin-shaped active regions,
wherein removing the second portions of the substrate results in formation of a first isolation recess between a first side of the planar active region and the plurality of fin-shaped active regions, and a second isolation recess adjacent to a second side of the planar active region opposing the first side,
wherein a bottom surface of the first isolation recess is at a first depth, relative to a top of the planar active region, after removing the second portions of the substrate,
wherein a bottom surface of the second isolation recess is at the first depth, relative to the top of the planar active region, after removing the second portions of the substrate, and
wherein the first depth is greater than a fin height of the plurality of fin-shaped active regions;
removing third portions of the substrate from the first isolation recess and from the second isolation recess,
wherein at least a portion of the bottom surface of first isolation recess is at a second depth, relative to the top of the planar active region, after removing the third portions of the substrate,
wherein the bottom surface of second isolation recess is at the second depth, relative to the top of the planar active region, after removing the third portions of the substrate, and
wherein the second depth is greater than the first depth; and
forming a first dielectric isolation region in the first isolation recess and a second dielectric region in the second isolation recess after removing the third portions.

9. The method of claim 8, wherein another portion of the bottom surface of the first isolation recess, in a stepped section of the first isolation, is at the first depth after removing the third portions of the substrate.

10. The method of claim 9, wherein the stepped section of the first isolation recess is covered by a masking layer while the third portions of the substrate are removed from the first isolation recess and from the second isolation recess.

11. The method of claim 8, wherein a first thickness of a hard mask layer on the top of the planar active region is less than a second thickness of the hard mask layer on the tops of the plurality of fin-shaped active regions after removing the third portions of the substrate.

12. The method of claim 11, wherein removing third portions of the substrate from the first isolation recess and from the second isolation recess comprises:
performing an etch operation to etch the substrate to remove the third portions of the substrate from the first isolation recess and from the second isolation recess,
wherein an oxygen-containing gas is used to control an etch selectivity between the substrate and the hard mask layer.

13. The method of claim 12, wherein a flow rate of the oxygen-containing gas in the etch operation is greater than 0 standard cubic centimeters per minute (sccm) and less than or approximately equal to 15 sccm.

14. The method of claim 8, wherein forming the first dielectric isolation region and the second dielectric region comprises:
depositing a dielectric layer in the first isolation recess and in the second isolation recess,
wherein the dielectric layer covers the planar active region; and
performing a planarization operation on the dielectric layer to remove the dielectric layer from the planar active region,
wherein the planarization operation results in formation of the first dielectric isolation region and the second dielectric region.

15. A semiconductor device, comprising:
a plurality of fin-shaped active regions extending above a substrate of the semiconductor device;
one or more fin-based transistor structures on the plurality of fin-shaped active regions;
a planar active region extending above the substrate of the semiconductor device;
a laterally diffused metal-oxide semiconductor (LDMOS) transistor structure on the planar active region; and
a dielectric isolation region between the planar active region and the plurality of fin-shaped active regions,
wherein the dielectric isolation region comprises:
a first portion in which a bottom surface of the dielectric isolation region is lower in the semiconductor device than bottoms of the plurality of fin-shaped active regions; and
a second portion in which the bottom surface of the dielectric isolation region is lower in the semiconductor device than the bottom surface of the dielectric isolation region in the first portion.

16. The semiconductor device of claim 15, wherein the first portion is adjacent to the planar active region; and
wherein the second portion is between the first portion and the plurality of fin-shaped active regions.

17. The semiconductor device of claim 15, further comprising:
a cut fin isolation region between the plurality of fin-shaped active regions and the isolation region.

18. The semiconductor device of claim 17, wherein the bottom surface of the dielectric isolation region in the first portion and in the second portion is lower in the semiconductor device than top surfaces of one or more cut fins in the cut fin isolation region.

19. The semiconductor device of claim 15, wherein a thickness of the dielectric isolation region decreases from the planar active region and the plurality of fin-shaped active regions.

20. The semiconductor device of claim 15, further comprising:
a plurality of dummy fins adjacent to the planar active region; and
another dielectric isolation region between the planar active region and the plurality of dummy fins,
wherein the other dielectric isolation region comprises:
a third portion in which a bottom surface of the other dielectric isolation region is lower in the semiconductor device than bottoms of the plurality of dummy fins; and
a fourth portion in which the bottom surface of the other dielectric isolation region is lower in the semiconductor device than the bottom surface of the other dielectric isolation region in the third portion.
